(19) United States
(12) Patent Application Publication
(10) Pub. No.: US 2020/0392616 A1
(43) Pub. Date: Dec. 17, 2020

(54) THIN FILMS OF NICKEL-COPPER BINARY OXYNITRIDE (NICUOxNy) AND THE CONDITIONS FOR THE PRODUCTION THEREOF

(71) Applicants: Gloria Ivonne Cubillos González, Bogotá (CO); José Edgar Alfonso Orjuela, Bogotá (CO); Karen Lizzette Velásquez Méndez, Guatavita (CO); Yadi Adriana Umaña Pérez, Bogotá (CO)

(72) Inventors: Gloria Ivonne Cubillos González, Bogotá (CO); José Edgar Alfonso Orjuela, Bogotá (CO); Karen Lizzette Velásquez Méndez, Guatavita (CO); Yadi Adriana Umaña Pérez, Bogotá (CO)

(21) Appl. No.: 16/634,133

(22) PCT Filed: Jul. 25, 2018
(86) PCT No.: PCT/IB2018/055522

§ 371 Date: Aug. 25, 2020

(30) Foreign Application Priority Data
Jul. 25, 2017 (CO) NC20170007378

(51) Int. Cl. C23C 14/06; C23C 14/02; C23C 14/35; C23C 14/34

(52) U.S. Cl. CPC C23C 14/0676; C23C 14/021; C23C 14/028; C23C 14/3414; C23C 14/35

(57) ABSTRACT

Thin films of nickel-copper binary oxynitride (NiCuOₓN_{y}) were deposited on the surface of AISI 3161 stainless steel and glass substrates using reactive phase RF sputtering with a thickness between 700 and 2100 nm under different deposition conditions from a bimetallic precursor target of nickel and copper under specific conditions, such as: base pressure, working pressure, argon flow, oxygen flow, nitrogen flow, power the Ni—Cu precursor target, target-substrate distance and deposition time. The films were characterized and made it possible to carry out a preliminary study of biocompatibility and a characterization according to their optical properties

This application is a 371 application of International Application No. PCT/IB2018/055522 filed Jul. 25, 2018; (published on Jan. 31, 2019 as WO/2019/021192) titled “Thin Films Of Nickel-Copper Binary Oxynitride (NiCuOₓN_{y}) And The Conditions For The Production Thereof”; the entire contents of which are hereby incorporated by reference herewith. This application also claims priority to Colombian Application No. CO20170007378 filed Jul. 25, 2017.

### FIELD OF THE INVENTION

The present invention describes a new material with ceramic properties and the conditions at which said material is produced. Specifically, the procedure describes the details for obtaining thin films of binary nickel-copper oxynitride (NiCuOₓN_{y}) by the method of sputtering RF in reactive phase, under different deposition conditions on the surface of stainless steel AISI 316L and glass. Depending on the deposit conditions, the thin NiCuOₓN_{y} films obtained are highly biocompatible and have characteristic optical properties.

### BACKGROUND OF THE INVENTION

Currently, materials science has set as a priority the development of new materials that have both excellent corrosion resistance properties and optoelectronic properties. Ceramic materials have been studied in recent years because some of them, when deposited in the form of thin films on the surface of alloys, such as steel, allow to improve their resistance to corrosion (Cubillos, et al., 2015; Wierzchon, T., et al., 2000; Pohrelyuk, I, et al., 2014). In addition, it has been observed that ceramic materials have optoelectronic properties such as being electric semiconductors and absorbing wavelengths in the ultraviolet region, which makes them attractive for the manufacture of functional devices such as solar cells (Lee, E., et al., 2016; Santana, G., et al., 2013; Zakutayev, A., 2016; Aroutiounian, V., et al., 2006). On the other hand, some have been described as highly biocompatible bioactive materials (Chang, Y., et al., 2013; Mitran, V., et al., 2015).

Within the broad group of ceramic materials are the oxynitrides of the transition metals (TMON), compounds formed by metal, oxygen and nitrogen (MₓO_{y}N_{z}). Studies carried out in the last decades have shown that this type of materials have high resistance to corrosion, dielectric and optical properties, which is why they are used in electronic devices (eg CuₓO_{y}N_{z} as in U.S. Pat. No. 8,822,283) and semiconductors (eg ZnₓO_{y}N_{z}, SnₓO_{y}N_{z} and GaₓO_{y}N_{z} as in U.S. Pat. No. 8,980,066). In addition, they are used as electrodes (eg LaₓO_{y}N_{z}, TaₓO_{y}N_{z} and NbₓO_{y}N_{z} as in U.S. Pat. No. 7,670,712), sensors (eg ZnₓO_{y}N_{z} reported on Rim, Y., et al., 2016), FET field effect transistors (eg SiₓO_{y}N_{z} as in U.S. Pat. No. 7,776,701), passivation films to protect metals from corrosion (eg NiₓO_{y}N_{z} as in U.S. Pat. No. 8,609,240), solar cells (eg SiₓO_{y}N_{z} as in patent US20080251121) and in the form of nano particles as photocatalysts in water treatment (eg LaTaON₂, TaₓO_{y}N_{z} and BaTa0₂N reported on Takata, T, et al., 2015; Ahmed, M. & Xinxin, G., 2016 or as in U.S. Pat. No. 6,878,666).

To date, a large amount of TMON has been synthesized by different methods, such as deposit by atomic layers (ALD) (Sowiñska, M., et al., 2016), citrate method for the formation of nanoparticles which can be used as non-toxic inorganic pigments (Aguiar, R., et al., 2008) and antimicrobial materials (Aiken, Z., et al., 2010), and the RF reactive spray method (Lu, Y., et al., 2013).

The method of sputtering RF in reactive phase is one of the most used techniques for the synthesis of thin films on different kinds of substrates such as silicon, glass, stainless steel and titanium (Cubillos, G., et al., 2013). The physical foundation for this technique, is the momentum exchange between ions (usually argon), and the atoms of a material located in a deposit chamber called blank. This exchange produces a plasma (Saraiva, M., 2012), which is formed by argon ions, ions of the blank material, reactive gas ions and electrons. This plasma is produced under specific conditions of potential difference, substrate temperature and pressure in the magnetron reservoir chamber. In the case of argon, the Ar⁺ ions are generated in high vacuum (between 10^{˜1} and 10^{˜3} Pa) when applying a potential difference. The generated electric field accelerates Ar⁺ ions to the target, resulting in a cascading collision that releases metal atoms by momentum exchange. Secondary electrons that are responsible for maintaining the plasma can also be released (Saraiva, M., 2012). The atoms expelled from the surface of the blank at these powers, reach energies of the order of keV. This amount of energy allows them to deposit on the surface of the substrate where they are adsorbed and then react in solid phase with the reactive gases supplied forming oxides, nitrides and/or oxynitrides. The growth of the film takes place through diffusion processes (Boukrouh, S., et al., 2012, Musil, J., et al., 2005, Jouan, P., et al., 2006).

Recently, we have synthesized binary oxynitrides transition metal (TMBO) of general formula ABOₓN_{y} with perovskite structure by the method of reactive sputtering, in order to obtain a synergistic effect between the physical and chemical properties of some monometallic TMON such as niobium-titanium oxynitrides NbTiON and silicon-titanium SiTiON (Vaz, et al., 2013), LiPON lithium-phosphorus oxynitride (Kim, Y. & Wadley, H., 2008) as well as thin semiconductor films of hafnium-zirconium oxynitride HfZrON described in U.S. Pat. No. 6,291,866, lanthanum-tantalum oxynitride LaTaON₂ (Takata, T., et al., 2015), tantalum-zirconium oxynitride Ta_{(3-X)}ZrₓN_{(5-X)}Oₓ (Aguiar, R., et al, 2008).

However, the stability of the TMBO strongly depends on the similarity between the atomic radius, electronegativity, valence and the crystalline structure of the two metals as well as their proportion in the final material; in some cases, it is only possible to achieve its synthesis in a limited range of compositions and temperature (Lumey, M. & Dronskowski, R., 2006).

On the other hand, in recent years the demand for orthopedic implants has increased for the treatment of bone anomalies such as fractures, complex surgeries such as total or partial hip arthroplasty and alternative in some cases of osteosarcoma (Buecker, P., et al., 2016); therefore, the field of research into new biomaterials is booming. It is estimated that about 4 billion dollars are invested annually for hip and knee replacement surgeries worldwide (Ramalingan, M., et al., 2012).

The most commonly used metallic materials for orthopedic surgery are surgical grade stainless steel (AISI 316L) (Ferreira, M. et al., 2003), cobalt-cobalt alloys Co—28Cr—6Mo (Sánchez, J., et. al., 2010), commercial pure titanium (cp. Ti) or its alloys as TÍ-6AI-4V and Ti-6AI-7Nb (Balaceanu, M., et al., 2008) due mainly to its good resistance to corrosion.

Stainless steel AISI 316L surgical grade is one of the most used biomaterials for the manufacture of prostheses due to its mechanical resistance, resistance to corrosion (generated by the passivation layer of Cr₂O₃ that protects the rest of the bulk material of corrosion), biocompatibility and relative low cost (Ratner, B., 2004). However, normal physiological conditions such as temperature, pH and ion concentration can accelerate the corrosion process of this material, which leads to a gradual loss of its constituent elements in the form of ions (such as Ni²⁺ and Cr³⁺), which in high concentrations can act as allergens in the surrounding cells inducing health problems related to the sensitivity to metals (Santonen, T., et al., 2010).

One solution to the problem is to coat the stainless steel with a biocompatible material (like a ceramic material) to take advantage of its mechanical properties. In addition, this material must be able to protect steel from corrosion and in turn promote osseointegration and cell proliferation. Zirconia Zr0₂ (Bianchi, M., et al., 2016), hydroxyapatite Ca₁₀(P0₄)₆(OH)₂ (Marinescu, C, et al., 2017; Parsapour, A., et al., 2013), alumina Al₂0₃ (Navarro, M., et al., 2008), titanium dioxide Ti0₂ (Majeed, A., et al., 2015), silicon dioxide Si0₂ (Jokanovic, V., et al., 2008), and TMON such as zirconia oxynitride ZrOₓN_{y} (Cubillos, G., et al., 2013), titanium oxynitride TiON (Pichugina, V., et al., 2016) and titanium-niobium oxynitride TiNbON (Probst, J., et al., 2001) are among this type of materials. Likewise, the U.S. Pat. No. 7,037,603 describes the use of oxynitrides (Si—ON, Al—ON and Al—Si—ON) as protective coatings against the degradation at low temperature of zirconia stabilized with yttria in biomedical implants (Vaz, F., et. al., 2013).

The optical properties such as the transmittance, reflectance and absorption of TMON can be evaluated as a function of the deposition conditions of the coating. These properties in turn depend on the microstructure, size, shape and volume of the particles that make up the material, as well as on the dielectric properties of the matrix (Torrell, M., et al., 2010). In addition, the optical constants of a thin film can be determined based on the transmission and optical reflection spectrum of the deposited material on a transparent and homogeneous solid substrate such as glass (Yang, X., et al., 2004).

The transmittance of a thin film deposited on a transparent substrate can be manipulated to find the refractive index and the absorption coefficient as a function of the wavelength of the incident radiation, in order to predict the photoelectric behavior of the same (Swanepoel, R., 1983; Hassanien, A., et al, 2016; Shaban, M., et al, 2017). In addition, the knowledge of these optical constants is necessary to find the optical band gap. The determination of the thickness of a film can be carried out using interferometric methods, in which, from the transmission and reflection spectra, the absorption coefficient (α) and the refractive index (η) can be determined by computational methods (Caglar, M., et al., 2006; Bhattacharyya, S., et al., 2009).

The present invention is carried out based on the aforementioned and on the following fundamental principles:

(a) It is well known that copper and nickel form a stable solid solution with monophasic structure in a wide range of proportions and temperatures (Sachtler, W. & Dorgelo, G., 1965).

(b) According to Nayan, N., et al. (2016), Kumar, S., et al. (2013), and Al-Kuhaili (2008), it is possible to deposit thin films of copper oxide Cu₂O—CuO on the surface of different types of solid substrates by different techniques, including the sputtering technique. This material has been described as a p-type semiconductor and its band gap (1.2 eV) is in an acceptable range for the conversion of solar energy, which is why it is used in numerous applications that include the field of solar cells and materials photovoltaic, electrochromic coatings, catalytic applications and also used as a high temperature superconductor. In addition, according to Norambuena, G., et al. (2016), the thin films of copper oxide in combination with TiO₂ are highly biocompatible and possess antimicrobial characteristics.

(c) According to Yue, G., et al. (2005), it is possible to deposit thin films of copper nitride Cu₃N on the surface of different types of solid substrates by the reactive cathodic sputtering technique. Depending on the deposition parameters, the thin films of nickel nitride Ni₃N are insulators (Maruyama, T. & Morishita, T., 1995) or metastable semiconductors (Caskey, C, et al., 2014), so they can be used in solar cells (Zakutayev, A., et al., 2014), resistive RAM memories (RRAIVI) and metallization layers (Caskey, C, et al., 2014). In addition, they have low thermal stability compared to other ceramic materials (decomposition temperature between 350-450° C.) (Yue, G., et al., 2005). In the work done by Ellenrieder, M., et al. (2011), the manufacture of biocompatible TiCuN coatings is described, where Cu₃N is responsible for the antibacterial characteristics of the material.

(d) The oxynitride films copper CuOₓN_{y} also can be deposited on different kinds of substrates by sputtering method (Du, Y., et al., 2007). Depending on the deposit conditions, this material can be used as an electrical conductor (Tuwei, A., et al., 2016) or p-type semiconductor in solar cells such as those described in patent US20120097227.

(e) Nickel oxide (NiO) in the form of thin films has a high chemical stability, excellent durability and, moreover, it is a promising material for the production of transparent electrically conductive films, for which reason it has application in organic light-emitting diodes (OLED), chemical sensors and in solar cells (Gomaa, M., et al., 2016). In addition, NiO has anti-ferromagnetic properties (Lu, Y., et al., 2002) and antibacterial activity against gram-positive and highly negative bacteria such as Escherichia coli and Bacillus atrophaeus, respectively (Xi, Y., et al., 2009).

(f) Thin films of nickel nitride (Ni₃N) can be obtained by methods such as nitriding in ammonia atmosphere and sputtering (Vempaire, D., et al., 2004). It has application as an electrode in lithium ion batteries and supercapacitors (Balogun, M., et al., 2015).

(g) According to what is described in US20120183766 patent, nickel oxynitride NiOₓN_{y} is a stable material that can be used as a coating to protect steel from corrosion at high temperatures.

(h) Finally, as mentioned above, previous studies have shown that a wide variety of transition metal oxynitrides are bio-inert, favor cell proliferation and are capable of protecting other materials against corrosion (Cubillos, G., et al., 2013; Pichugina, V., et al., 2016; Probst, J., et al., 2001).

Titanium and alloys possess excellent corrosion resistance properties due to the formation of a layer of TiO₂ on its surface which, in addition to acting as a passivation layer, is also bio-inert. However, its great disadvantage is the high cost of production (20 to 35 dollars per gram of pure titanium) which is why the industry have modified the surface of materials such as stainless steel (1 to 5 dollars per gram) (Escobar, A, 2012). In addition, it has been observed that due to the low resistance to friction of titanium and some of its alloys, TiO₂ microparticles can be released to the organism causing allergies, sensitization (Evrard, L, et al., 201 0) and in some osteosarcoma cases (Dunn, A., et al., 2012).

Thin films of TMON also have characteristic optical properties, which is why they have a wide industrial application as semiconductors in electronic devices and solar cells (US20090233424; US 20080251 121), manufacture of decorative optical coatings (Fuertes, A., 2015, Carvalho, P., et al., 2015), photocatalysts (Takata, T, et al., 2015, Ahmed, M. & Xinxin, G., 2016) and as photovoltaic devices (Garcia, A. et al., 2016).

### BRIEF DESCRIPTION OF THE INVENTION

The present invention describes the conditions for obtaining thin films of NiCuOₓN_{y} highly biocompatible based on the results obtained from a previous biocompatibility study where the capacity of the coatings was analyzed to favor cellular processes such as proliferation and osseointegration. Additionally, the present invention also discloses the conditions for manufacturing thin films of NiCuOₓN_{y} with characteristic optical properties, whereby they can be considered within the broad group of semiconductor materials with photovoltaic applications.

Based on the principles mentioned in the state of the art, the present invention describes a new material with ceramic properties: binary nickel-copper oxynitride (NiCuOₓN_{y}) deposited in thin film form on substrates of stainless steel AISI 316L by the technique of sputtering RF in reactive phase, whose physical and chemical properties can be understood as a set of synergistic properties of oxides, nitrides and/or oxynitrides of individual metals: CuO—Cu₂O, Cu₃N, CuOxNy, NiO, Ni₃N and NiOₓN_{y}, for which the material may have application as semiconductor and/or insulator in solar cells, superconductor at high temperatures, electronic devices and in catalysis depending in turn on the deposit parameters during its manufacture in the form of a thin film by sputtering.

### BRIEF DESCRIPTION OF THE FIGURES

FIG. 1a and FIG. 1b depicts a schematic of the material with ceramic properties claimed and an image of some of the NiCuOₓN_{y} products obtained in the present invention. In FIG. 1a, the support (102) of NiCuOₓN_{y} material is a substrate of AISI 316L stainless steel previously polished to 600 grit; this support is partially or completely covered by a thin film of binary nickel-copper oxynitride NiCuOₓN_{y} (101), where the nickel and copper atoms are arranged in a solid solution forming covalent bonds with the atoms of oxygen and nitrogen. FIG. 1.b shows a photograph of the product NiCuOₓN_{y}-10₄₃₃72₂₅₀ manufactured.

FIG. 2 depicts a simplified diagram of the procedure used to manufacture thin films of binary nickel-copper oxynitride NiCuOₓN_{y} on the surface of stainless steel AISI 316L by the technique of sputtering RF in reactive phase. The substrates (1) of stainless steel AISI 316L are arranged in the sample holder (2) of the vacuum chamber; the cathode is composed of a nickel-copper target (3) with nickel composition between 72% and 90%; vacuum is generated by means of a mechanical pump and a turbomolecular (4). The plasma (5) is generated by means of argon gas (6); Oxygen (7) and nitrogen (8) reactive gases are used, whose pressures and flows are controlled by means of valves (9) and flow meters (10). Once the working pressure is established between 7.2×10-1 and 7.6×10-1 Pa, it begins with the deposit of the coatings of NiCuOxNy by supplying the power (11) to the Ni—Cu target; the power and temperature of the oven (12) is monitored throughout the process by means of a thermocouple (13) disposed on the steel substrates (1), which is connected to the temperature controller (14) of the power source of the oven (15). The shutter (16) protects the substrates during the cathodic pre-sputtering stage in which possible interferences from the surface of the Ni—Cu target are eliminated.

FIG. 3 shows a comparison between the diffractograms obtained for the AISI 316L steel (301) and the NiCuOxNy-1843372250 (302) and NiCuOxNy-1043372250 (303) products obtained by the claimed conditions. The X-ray diffraction signals corresponding to copper oxide (CuO), nickel-copper oxynitride (NiCuOxNy) and austenite of the AISI 316L stainless steel substrate, obtained when compared against the X-Pert® database.

FIG. 4a and FIG. 4b depict the images obtained by scanning electron microscopy (SEM) for the products NiCuOxNy-1857372250 (FIG. 4a) and NiCuOxNy-1843390250 (FIG. 4b) with a magnification of 20000× and scale of 5.0 μm.

FIG. 5a and FIG. 5b shows one of the images obtained by nanosem for the product NiCuOxNy-1843314250 (FIG. 5a) and the image obtained by atomic force microscopy (MFA) for the product NiCuOxNy-843390250 (FIG. 5b).

FIG. 6a, FIG. 6b, FIG. 6c and FIG. 6d presents the high resolution spectra for O 1s (FIG. 6a), N 1s (FIG. 6b), Ni 2p (FIG. 6c) and Cu 2p (FIG. 6d), obtained from spectroscopy of x-ray photoelectrons (XPS) for the product NiCuOxNy-1043372250.

FIG. 7a and FIG. 7b depict one of the images obtained by fluorescence microscopy (magnification 10×, scale 500 nm) of mouse osteoblasts C57BL/6 cell line seeded on the surface of the product NiCuOxNy-1843372250 (FIG. 6a). In addition, one of the images obtained by scanning electron microscopy (SEM) of the mouse osteoblasts (cell line C57BL/6) seeded on the surface of the product NiCuOxNy-1843372250 (FIG. 6.b) is shown.

FIG. 8a and FIG. 8b shows the images obtained by scanning electron microscopy (SEM) of the hydroxyapatite crystals HAP formed by hydrothermal treatment on the surface of the product NiCuOxNy-1043390250 with magnification 100'3 (FIG. 6a) and 1000× (FIG. 6b).

FIG. 9 depicts the voltammogram obtained for the determination of the Ni2⁺ ion release rate for the product NiCuOxNy-1043390250 at time t=192 h after 8 successive additions of standard Ni2⁺ solution 283.5 ppb.

FIG. 10 is the calibration curve obtained for the voltammetrogram of the product NiCuOxNy-1043390250 at time t=192 h.

FIG. 11 shows the transmittance spectrum of the products NiCuOxNy-457314200, NiCuOxNy-457314250 and NiCuOxNy-457314300 deposited in thin film form on glass substrates by the reactive RF sputtering method, obtained by applying a target power of 200, 250 and 300 W, respectively.

FIG. 12 depicts the variation of the absorption coefficient of the products NiCuOxNy-457314200 (N4W200), NiCuOxNy-457314250 (N4W250) and NiCuOxNy-457314300 (N4W300) as a function of the wavelength (λ). The products were deposited in thin film form on glass substrates by the sputtering method in RF reactive phase, applying a target power of 200, 250 and 300 W, respectively.

FIG. 13 shows the variation of the factor (αhu)2 with the energy of the incident photon (hu). The highest degree of linearity was obtained for the optical transition mode factor n= 1/2 indicating that a direct transition allowed in the NiCuOxNy material takes place. The determination of the optical gap energy (Eg) is shown for the products NiCuOxNy-457314200 (N4W200), NiCuOxNy-457314250 (N4W250) and NiCuOxNy-457314300 (N4W300) deposited in thin film form on glass substrates by the method of cathode sputtering in RF reactive phase, obtained by applying a power to the target of 200, 250 and 300 W, respectively.

### DETAILED DESCRIPTION OF THE INVENTION

The following is a detailed description of each of the stages of the procedure performed:

### 1. Preparation of the Substrate Surface

AISI 316L stainless steel sheets were cut by a Struers Labotom-3® cutter to obtain specimens of certain dimensions (1.0×1.5 cm in a preferred case). Subsequently, a metallographic preparation was carried out with 80, 240, 320 and 600 grit silicon carbide sandpapers in a Knuth Rotor-3® chipper cooled with water. Once the 600 grit finish was reached, the surface of the specimens was examined under the optical microscope until a homogeneous surface appearance was confirmed.

Once polished, each test piece was washed with liquid soap and tap water in order to remove organic and inorganic impurities. To remove the remaining organic impurities, a surface cleaning of the substrate with isopropanol was performed. This process was carried out to remove as much impurities as could interfere with the adhesion of the NiCuOₓN_{y} coating to the substrate.

### 2. Cleaning the Nickel-Copper Target by Sputtering with Argon Plasma

In order to deposit the thin films of binary nickel-copper oxynitride on the surface of substrates made of AISI 316L stainless steel, an Alcatel model HS® 2000 cathode sputtering equipment was used. The equipment comprises a DC source, a 13.8 MHz RF source with variable power from 0 to 1 KW and a vacuum device integrated by a chamber, two vacuum pumps (mechanical and turbomolecular), reactive gas inlet, inert gas inlet, flow controllers and pressure controllers.

Different deposit conditions were used: blank composition, temperature, power applied to the target and nitrogen flow. For this, a bimetallic blank precursor of nickel (99.9% in purity) and copper (99.9% in purity) of dimensions 4″×¼″ with nickel composition between 14% and 90% by weight was used. The blank-substrate distance was adjusted to 5.0 cm and remained constant in all experiments. Argon (99.999% purity) was used as the inert gas generating the plasma, and as reactive gases nitrogen (99.999% purity) and oxygen (99.999% purity).

The AISI 316L stainless steel substrates of the first step were placed in the sample holder of the vacuum chamber of the RF sputtering equipment. Before starting with the deposition of thin films NiCuOₓN_{y}, blank cleaning was performed by sputtering to remove interferents that may affect the final composition of the coatings.

In the step of cleaning the target by cathodic spraying, substrates of AISI 316L steel were protected with the shutter and vacuum was made with the mechanical pump until reaching a pressure between 1.0×10^{˜1} and 1.5×10^{˜1} Pa. Once this pressure was reached, the turbo molecular pump was ignited until reaching a base pressure between 3.0×10^{˜3} and 3.5×10^{˜3} Pa and simultaneously, heating of the oven was started at a temperature between 433 K and 573 K with a ramp of 4° C./min. Vacuum was carried out for 2.5 h before starting the discharge. Then, the discharge power unit was switched on (power between 240 and 350 W) and argon was fed to the system (flow of Ar between 18.0 and 22.0 sccm) until reaching a pressure between 4.0×10^{˜1} and 4.5×10^{˜1} Pa. The stage of plasma cleaning of Ar⁺ lasted for 5 min.

### 3. Deposit of the Thin Films of Binary Nickel-Copper Oxynitride (NiCuOₓN_{y}) on the Surface of Stainless Steel AISI 316L

After the Ar⁺ plasma cleaning step, maintaining a constant Ar pressure between 4.0×10^{˜1} and 4.5×10^{˜1} Pa and an Ar flow between 18.0 and 22.0 sccm, nitrogen is slowly fed into the system until reaching a pressure between 5.0×10^{˜3} and 5.5×10^{˜3} Pa. In this step, different nitrogen fluxes (N₂ flow between 8.00 to 18.0 sccm) were used in order to obtain films with different deposit conditions. Once the pressure remained stable, oxygen was slowly fed at a constant flow of 2.00 sccm into the chamber until reaching a working pressure between 7.2×10^{˜1} and 7.6×10^{˜1} Pa.

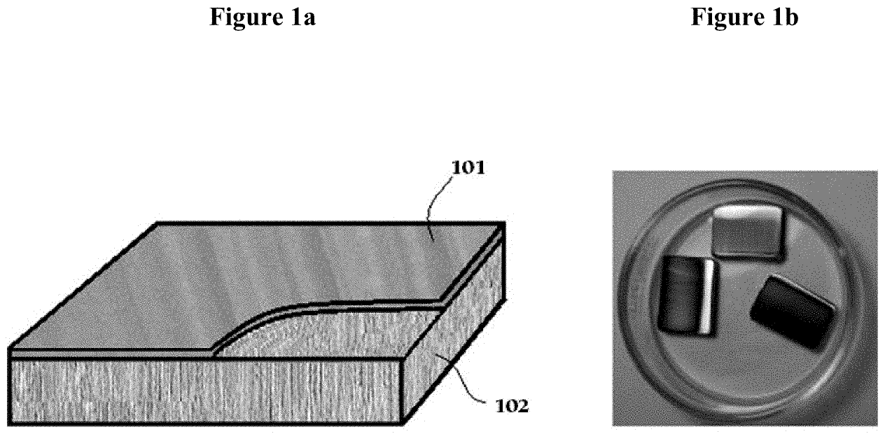

Once the reactive gas mixture was fed to the chamber, the shutter was removed to allow the deposition of nickel-copper binary oxynitride (NiCuOₓN_{y}) coatings in thin film form and started with the deposit time count 60 min. Throughout the process it was verified that the working pressure, gas flows and target power were maintained within the ranges indicated above. As an example, FIG. 1a depicts the scheme of the material with ceramic properties claimed and FIG. 1b shows a photograph of the product NiCuOₓN_{y}-1043372250 (whose deposit conditions are mentioned below) obtained in the present invention, where (101) corresponds to the substrate of stainless steel AISI 316L and (102) the coating of NiCuOₓN_{y} in the form of thin film deposited by sputtering RF in reactive phase.

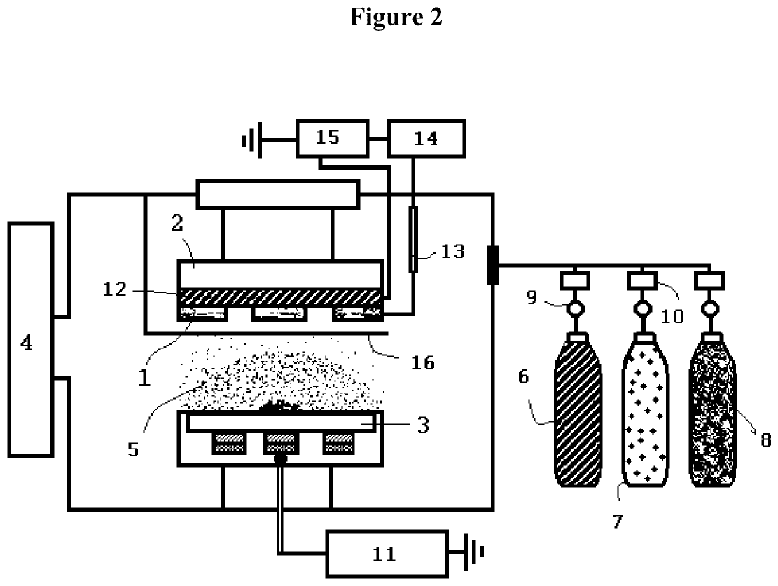

FIG. 2 shows a simplified scheme of the process used to manufacture thin films of binary nickel-copper oxynitride NiCuOₓN_{y} on the surface of AISI 316L stainless steel by the RF sputtering technique in reactive phase. The system consists of substrates (1) of stainless steel AISI 316L, a sample holder (2), blank Ni—Cu (3), vacuum system (4) composed of a mechanical pump and a turbomolecular, plasma (5) of argon as inert gas (6), the reactive gases oxygen (7) and nitrogen (8), gas valves (9), flow controllers (10), potential source (11), furnace (12), thermocouple (13)), controller temperature (14), oven power source (15) and shutter (16) to protect the substrates during the cleaning stage.

Table I shows some of the NiCuOₓN_{y} products obtained in the present invention under the claimed conditions.

TABLE I
Deposit conditions for some thin NiCuOxNy films
deposited on AISI 316L stainless steel by the
RF sputtering technique in reactive phase.

| | Ni | | | |
|---|---|---|---|---|
| | Composition | N₂ Flow | Temperature | Power |
| Material Code | (%) | (sccm) | (K) | (W) |
| NiCuOₓN_{y}-10₄₃₃90₂₅₀ | 90 | 10 | 433 | 250 |
| NiCuOₓN_{y}-18₄₃₃90₂₅₀ | 90 | 18 | 433 | 250 |
| NiCuOₓN_{y}-18₅₇₃90₂₅₀ | 90 | 18 | 573 | 250 |
| NiCuOₓN_{y}-18₅₇₃72₂₅₀ | 72 | 18 | 573 | 250 |
| NiCuOₓN_{y}-18₄₃₃72₂₅₀ | 72 | 18 | 433 | 250 |
| NiCuOₓN_{y}-10₄₃₃72₂₅₀ | 72 | 10 | 433 | 250 |
| NiCuOₓN_{y}-10₅₇₃90₂₅₀ | 90 | 10 | 573 | 250 |
| NiCuOₓN_{y}-4₅₇₃l4₂₀₀ | 14 | 4 | 573 | 200 |
| NiCuOₓN_{y}-4₅₇₃14₂₅₀ | 14 | 4 | 573 | 250 |
| NiCuOₓN_{y}-4₅₇₃l4₃₀₀ | 14 | 4 | 573 | 300 |
| NiCuOₓN_{y}-10₃₂₃72₃₅₀ | 72 | 10 | 323 | 350 |

### 4. Characterization of the Thin Films of Binary Nickel-Copper Oxynitride (NiCuOₓN_{y}) Obtained

The characterization of the product obtained was carried out by X-ray diffraction (XRD) using a Philips® diffractometer operated at 30 kV and 20 mA, working in the Bragg-Brentano configuration with the Ka radiation of Cu. The morphology of the surface as well as a semi-quantitative measurement of its Cu and Ni composition was analyzed by scanning electron microscopy (SEM) with EDX (X-ray dispersive energy spectroscopy) with a Quanta 2000® MEB microscope operated at 15 kV and 10 mA. The thickness of the NiCuOₓN_{y} coatings was determined by a DEKTAK 150 profilometer with a resolution of 0.056 μm. A sweep of 2000 μm was recorded for 120 s. The applied force was 1 mg. The measurement was made by the difference between the coated area and the uncoated zone obtained from a silicon step that is placed before the deposit and then removed before measuring the thickness.

The roughness of the coatings and the particle size was determined by atomic force microscopy in an Auto-probe CP5 instrument from Park Scientific Instruments, operating in non-contact mode. Each of the 3D images was processed using the PSI ProScan Image Processing software. The tip radius used was 10 nm and the study area was 25 mm², with frequencies of 2 and 10 Hz.

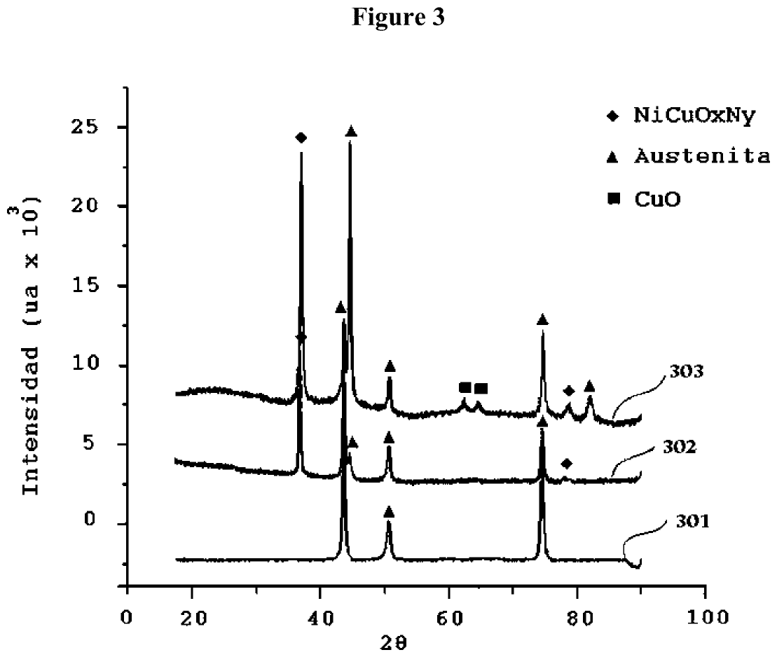

FIG. 3 shows a comparison between the X-ray diffractograms obtained for the AISI 316L stainless steel substrate (301) and the manufactured products: NiCuOₓN_{y}-1843372250 (302) and NiCuOₓN_{y}-1043372250 (303). The X-ray diffraction signals corresponding to copper oxide (CuO), nickel-copper oxynitride (NiCuOₓN_{y}) and austenite of the AISI 316L stainless steel substrate, obtained when compared against the X-Pert® database, are shown.

In general, the deposit parameters strongly determine the surface characteristics of the final coating; some of the manufactured NiCuOₓN_{y} films presented amorphous characteristics, while others are polycrystalline (such as the product NiCuOₓN_{y}-1043372250) or grow preferentially in a crystalline plane (for example the product NiCuOₓN_{y}-1843372250) depending on the type of substrate, temperature, nitrogen flow and proportion of nickel in the final coating.

Also, some NiCuOₓN_{y} films showed growth crystalline preferential at 2θ=37°, signal that does not correspond with any of the diffraction signals reported in the X-Pert® database and with that reported in the literature for the oxides and nitrides of the two individual metals (monoclinic phase CuO JCPDS 00-001-1117; cubic system NiO JCPDS 00-047-1049, cubic phase Cu3N JCPDS 86-2283 and hexagonal system Ni3N JCPDS 10-0280) whereby this signal is attributed to the formation of binary oxynitride nickel -copper (NiCuOₓN_{y}).

On the other hand, profilometry analysis allowed to determine that the thickness of the thin NiCuOₓN_{y} films manufactured is between 700 to 2100 nm depending on the deposit conditions.

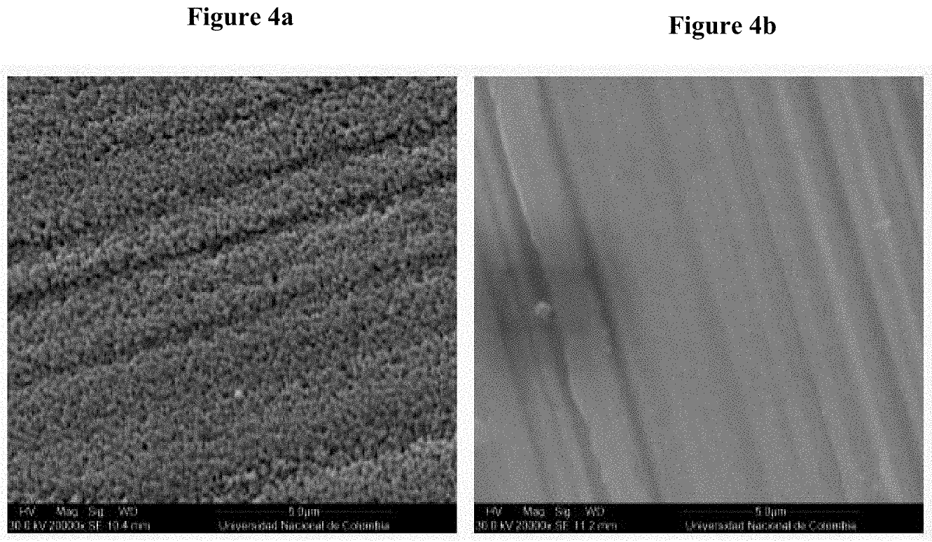

FIG. 4a and FIG. 4b show the images obtained by scanning electron microscopy (SEM) obtained for the products NiCuOₓN_{y}-1857372250 (FIG. 4a) and NiCuOₓN_{y}-1843390250 (FIG. 4b) with a magnification of 20000× and scale of 5.0 where it can be seen that the deposition conditions determine the surface morphology of the products manufactured in the present invention. Finally, the results of the X-ray dispersive energy (EDX) analysis corroborated the presence of copper and nickel in the manufactured films.

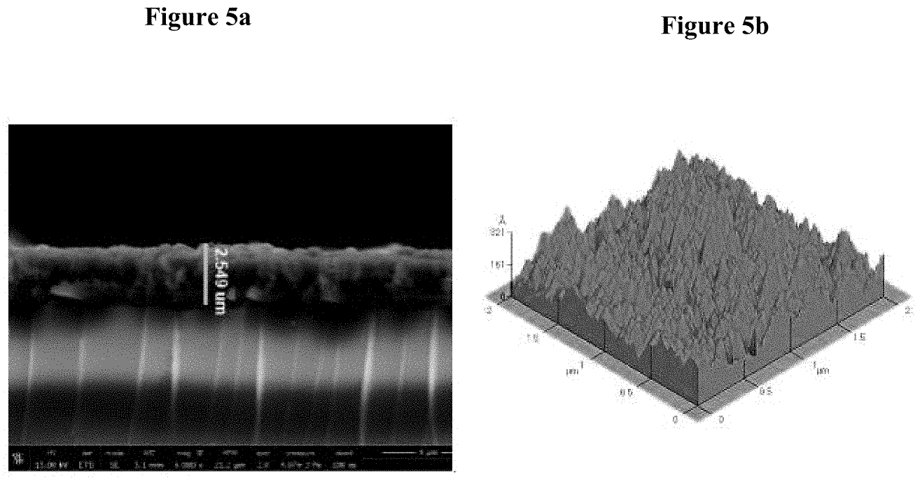

FIG. 5a and FIG. 5b show one of the images obtained by nanosem for the product NiCuOₓN_{y}-1843314250 (FIG. 5a) and the image obtained by atomic force microscopy (MFA) for the product NiCuOₓN_{y}-843390250 (FIG. 5b).

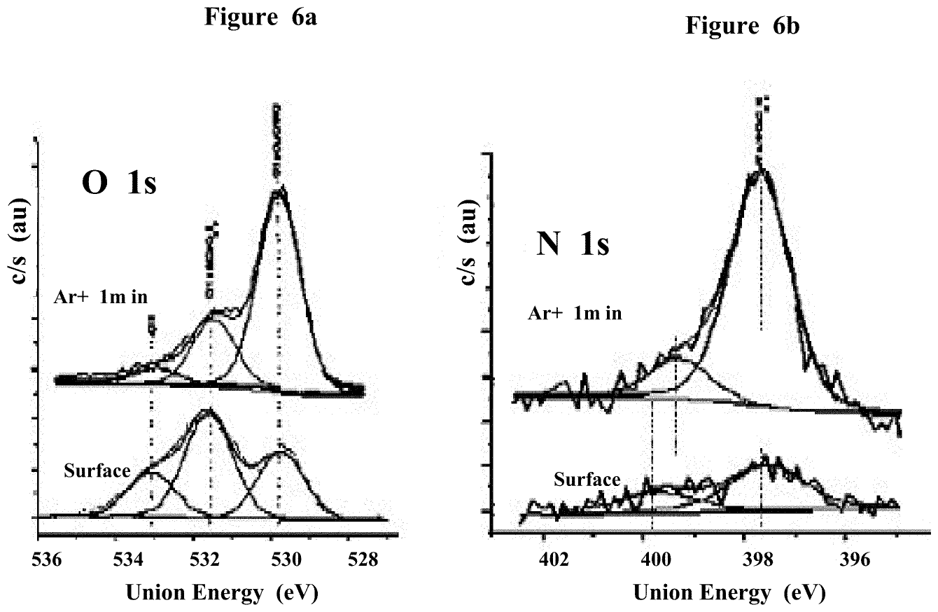

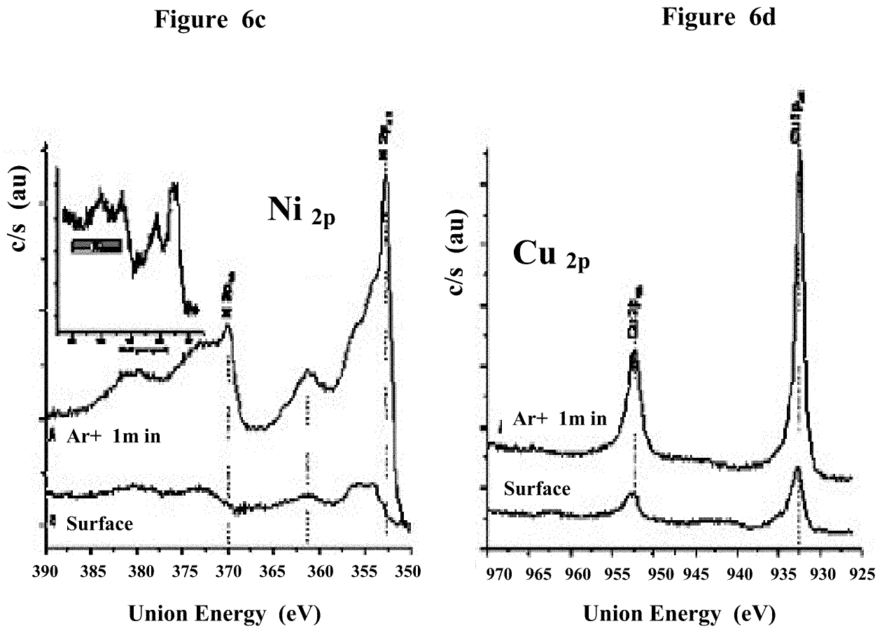

The chemical composition of the NiCuOₓN_{y} thin films was determined from X-ray photoelectron spectroscopy (XPS). The high-resolution spectra were recorded on the surface and after a 1-minute cleaning with Ar⁺ to evaluate the stability of the coating with the atmosphere. FIG. 6a, FIG. 6b, FIG. 6c and FIG. 6d show the high-resolution spectra for oxygen (O1s) (FIG. 6a), nitrogen (N1s) (FIG. 6b), nickel (Ni2p) (FIG. 6c) and copper (Cu2p) (FIG. 6d). The signals for O1 to ligature energies (BE) of 533.1, 531.6 and 529.8 eV on the surface of the film indicate presence of —OH groups product of the interaction of the film with atmospheric water vapor, at 531.6 eV are characteristic of oxynitrides and identify the binding energy for NiCuOₓN_{y} and the signal at 529.8 eV indicates the presence of oxides of the corresponding metals. After a 1-min cleaning with Ar⁺ ion, the oxide to oxynitride ratio is 60:40 according to the area under the curve and there is no displacement in the binding energy of any of the species present in the film, which shows the stability of the film against the atmosphere.

For N1s the binding energy at 397.7 eV and 399.3 eV, indicate the presence of two different chemical species of NiCuOₓN_{y} oxynitride, wherein the degree of substitution of oxygen by nitrogen is greater for the former, in comparison with the signal at 399.3 eV, where the highest BE indicates greater electronegativity due to the greater oxygen composition. For metals, the spectrum for Ni2p is typical of nickel oxide. However, the separation range of doublet Ni2p3/2 and Ni 2p1/2 is 17.8 eV, lower by 0.6 eV than that reported for NiO (18.4 eV); this indicates changes in the electronegativity generated by the substitution of oxygen by nitrogen (Liu, H., et al., 2008; Ai, L, et al., 2008, Zhang, Y., et al., 2015). For the copper spectrum, the signal at 932.5 eV for Cu 2p3/2 and at 952.33 eV for Cu 2p1/2 corresponds to Cuo or Cu1+; However, the absence of satellites characteristic of Cu2O due to its closed layer configuration ([Ar] 3d10) allows to eliminate the presence of Cuo and confirm that of Cu⁺ (Peng, D., et al., 2006; Hossaina, M., et al., 2017; Platzman, I., et al., 2008).

In order to determine the deposition conditions under which highly biocompatible NiCuOₓN_{y} thin films are obtained, different biocompatibility analyzes were performed as shown below.

### 5. Biocompatibility Assays of Thin NiCuOxNy Films

To evaluate the biocompatibility properties of the synthesized nickel-copper binary oxynitride films and determine the most suitable deposition conditions for obtaining thin films of NiCuOₓN_{y} biocompatible, four tests were performed: MTT cell viability analysis, cell count of osteoblasts on the surface of the film synthesized from NiCuOₓN_{y} by fluorescence microscopy, formation of hydroxyapatite on the surface and analysis of the biodegradability of the films in vitro under simulated physiological conditions by means of the determination of the rate of release of the Ni²⁺ ion from the surface of the coating by the technique of voltammetry of adsorptive cathodic redissolution by square wave (VRCAdOC).

### 5.1 MTT Cell Viability Assay

Cell viability analyzes were carried out with mouse osteoblasts (cell line C57BL/6). 7000 cells were seeded per cm² of surface area of each NiCuOₓN_{y} product manufactured. Cells were incubated at 37° C. and 5% CO₂ with supplemented medium Dulbecco® modified Eagle (DMEM, Thermo Fisher Scientist, USA) at 10% v/v in fetal bovine serum (SFB), 50 μg/mL ascorbic acid, 10 mM β-glycerophosphate and Clavamox® 1× as an antibiotic. The incubation time was 72 hours. After this time, the medium was discarded and 50 L of MTT reagent (3-(4,5-dimethylthiazol-2-yl)-2,5-diphenyltetrazolium bromide) of concentration 50 mg/mL together with 1.5 mL of DMEM medium in each sample was added. It was incubated at 37° C. and 5% C02 for 4 hours. After this time, the purple formazan crystals were dissolved in 1.5 mL of 1% SDS in 0.01 M HCl and 100 L of solution from each MTT well were taken to a 96-well box. Finally, the measurement of absorbance (Abs) was made in a Bio-Rad® ELISA spectrophotometer at 570 nm.

The results showed that the product NiCuOₓN_{y}-1857390250 is about 1.5 times more biocompatible with mouse osteoblasts than the AISI 316L steel used as a reference. However, it was observed that some of the products of NiCuOₓN_{y} manufactured are unstable against the action of the tetrazolium salt (MTT), for which reason it was decided to evaluate the cellular viability of the material by means of another highly sensitive technique: fluorescence microscopy.

### 5.2 Cell Count by Fluorescence Microscopy

Seven thousand osteoblasts were seeded per cm² of surface area of the thin films of binary nickel-copper oxynitride (NiCuOₓN_{y}) synthesized under different deposition conditions. The samples were incubated with 1.5 mL of medium supplemented DMEM 10% SFB with the stimuli mentioned above (ascorbic acid and β-glycerophosphate) at 37° C. and 5% C0₂ for 72 hours. After this time, the medium was discarded, the samples were washed in duplicate in phosphate buffered saline (BFS) pH 7.4 and 1.5 mL of fluorescent marker solution Hoechst 33342® of concentration 5 μg/mL in BFS pH 7.4 was added. The samples were incubated for 30 minutes and washed with BFS three times in order to eliminate excess marker. The amount of osteoblasts adhered to the surface of the material was determined by nucleus counting in an Olympus® BX41 fluorescence microscope and the ImageJ® computer program. The data were analyzed for the number of osteoblasts/cm² of surface area and the degree of biocompatibility was determined by comparison with what was established in ISO 10993-12 for biomaterials.

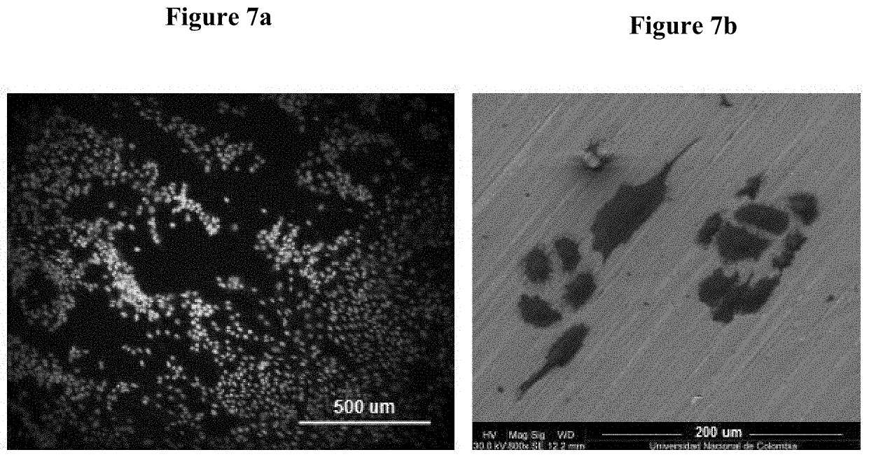

FIG. 7a shows one of the images obtained by fluorescence microscopy (magnification 10×, scale 500 nm) of mouse osteoblasts cell line C57BL/6 seeded on the surface of the product NiCuOₓN_{y}-1843372250.

Table II shows the biocompatibility results obtained for some of the NiCuOₓN_{y} products manufactured. The classification of some of the products obtained in the present invention according to the international standard ISO 10993-12 (In Vitro Cytotoxicity Tests: Biological Evaluation of Medical Devices) is shown, based on the results of the biocompatibility analysis by microscopy of fluorescence. The same analysis was performed with a nickel substrate electrolytic grade by way of comparison.

TABLE II
Classification of some of the thin films deposited on
NiCuOx N_{y} steel AISI 316L according to ISO 10993-12.
Where (AB): highly biocompatible, (BC): biocompatible,
(MC): moderately cytotoxic, and (CT): cytotoxic.

| | ISO 10993-12 |
|---|---|
| Material | Classification Code |
| NiCuOₓN_{y}-10₄₃₃90₂₅₀ | BC |
| NiCuOₓN_{y}-18₄₃₃90₂₅₀ | CT |
| NiCuOₓN_{y}-18₅₇₃72₂₅₀ | MC |
| NiCuOₓN_{y}-18₄₃₃72₂₅₀ | AB |
| NiCuOₓN_{y}-10₄₃₃72₂₅₀ | AB |
| NiCuOₓN_{y}-10₅₇₃90₂₅₀ | BC |

### 5.3 Cell Morphology by Scanning Electron Microscopy

The morphology of the osteoblasts adhered to the surface NiCuOₓN_{y} films was determined by scanning electron microscopy (SEM) in a Quanta 2000® microscope operated at 15 kV and 10 mA. A sample of AISI 316L steel polished at level 600 with silicon carbide was used as a target. 7000 cells/cm² were seeded on each NiCuOₓN_{y} film and the system was incubated at 37° C. and 5% CO₂ for 72 hours with supplemented medium DMEM at 10% SFB. The osteoblasts were fixed on the surface of the material according to what was reported by (Hosseini, S., et al., 2014): the samples were immersed in a 2.5% glutaraldehyde solution in BFS 0.1 M pH 7.4 for 4 hours. Then, the samples were washed twice with BFS and the cells were dehydrated by immersion in aqueous ethanol solutions of increasing concentrations for 10 minutes each (in order): 30%, 50%, 60%, 80% and 96% v/v. The samples were allowed to dry in a desiccator at room temperature for two hours before analysis by MEB microscopy. The results showed that in general, the osteoblastic cells used for the analysis are capable of forming different anchor points with different products of the claimed material.

FIG. 7b shows one of the images obtained by scanning electron microscopy (SEM) of the mouse osteoblasts (cell line C57BL/6) seeded on the surface of the product NiCuOₓN_{y}-1843372250.

### 5.4 Hydrothermal Treatment for the Formation of Hydroxyapatite (HAP)

This analysis was performed based on what was reported by (Hosseini, S., et al., 2014). In order to evaluate the osseointegration and bioactivity properties of the NiCuOₓN_{y} films deposited on AISI 316L steel, a coating sample was immersed in 40.0±0.1 mL of a solution containing 3.3 mM CaCl₂ and 1.6 mM NaH₂P0₄ (equivalent concentrations). to human physiological concentrations of calcium and phosphorus) in a buffer Tris-HCl 0.1 M pH 7.4 in a thermostat at 37.0±0.1° C., without agitation for 120 hours. The pH of the solution remained constant throughout the time of analysis. After this time, the PAH crystals obtained were carefully washed with 96% v/v ethanol aqueous solution and allowed to dry at room temperature (20° C.). A sample of uncoated AISI 316L stainless steel was used as a blank. The crystals of PAH Ca₁₀(P0₄)₆(OH)₂ obtained were characterized by scanning electron microscopy (SEM), X-ray dispersive energy spectroscopy (EDX) and X-ray diffraction (XRD).

From the results it was found that nickel-copper binary oxynitride NiCuOₓN_{y} films favor osseointegration since, for example, in the product NiCuOₓN_{y}-1043390250 the PAH crystals formed covered about 39.4% of the total surface area of the film while the PAH formed on uncoated AISI 316L steel was only 3.8%.

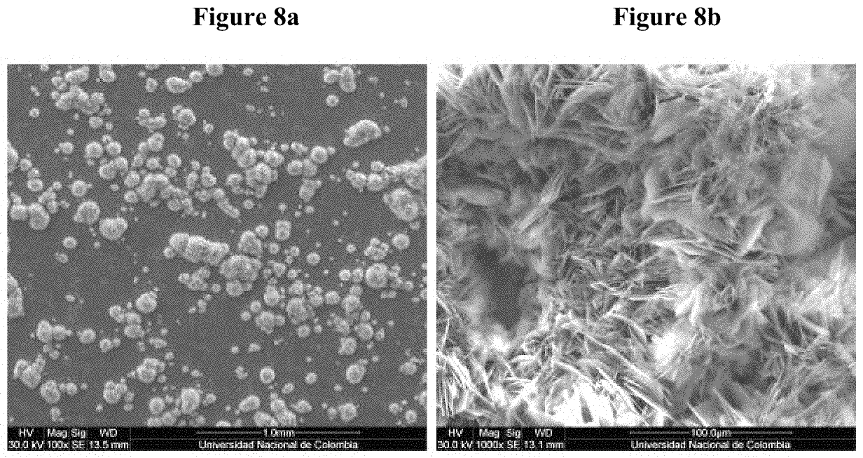

FIG. 8a and FIG. 8b show the crystals of PAH formed by hydrothermal treatment under simulated physiological conditions on the surface of the product NiCuOₓN_{y}-1043390250 with magnification 100× (FIG. 8a) and 1000× (FIG. 8b), observed by scanning electron microscopy (MEB) It was found that the crystals of PAH present preferential growth in the crystalline planes (002) and (211) and the Ca/P ratio in them is around 1.73, value according to the Ca/P ratio found in the cortical bones (Ca/P 1.2 a 2) (Guzmán, R., et al., 2005).

### 5.5 Determination of Nickel Release Rate under Simulated Physiological Conditions

The procedure was performed according to international standards ASTM STP859 for analysis of in vitro degradation of orthopedic materials (Fraker, A. & Griffin, C, 1985). One sample of NiCuOₓN_{y} and another of stainless steel AISI 316L (control) were individually immersed in 150 mL±0.2 mL of Hank's physiological solution at pH 7.22 for 8 days at 37° C. +/−1° C. with constant agitation. Aliquots of 10.0±0.1 mL were taken every 0, 24, 96, 120, and 192 hours. The quantitative determination of nickel was carried out on a BAS CV50® voltammetric analyzer by the adsorptive cathodic redissolution voltammetry technique of the Ni-(DMG) 2 complex per square wave (VRCAdOC) on a bismuth film (working electrode) generated in situ on the surface of a vitrified carbon electrode (concentration of Bi3+ in the cell: 10 ppm, deposit parameters of bismuth film: −1.1 V for 60 seconds with constant agitation, accumulation of Ni (DMG) 2−0.8 V per 120 s, potential sweep: −0.8 to −1.3 V, frequency: 25 Hz, potential step: 0.005 V, pulse time: 0.04 s). An Ag/AgCl electrode saturated in 0.1 M KCI and a platinum electrode were used as reference electrode and electrode, respectively. A buffer of NH₄Cl/0.1 M NH3 pH 9.0 was used as support electrolyte. Interferences by other ions present in the sample were eliminated by the addition of 100 L of 1.0 M sodium potassium tartrate solution in the voltammetric cell. The quantification method was standard addition with 100 L additions of standard Nickel 283.5 ppb to the electrochemical cell (range of known concentrations of Ni²⁺ between 2 and 20 ppb).

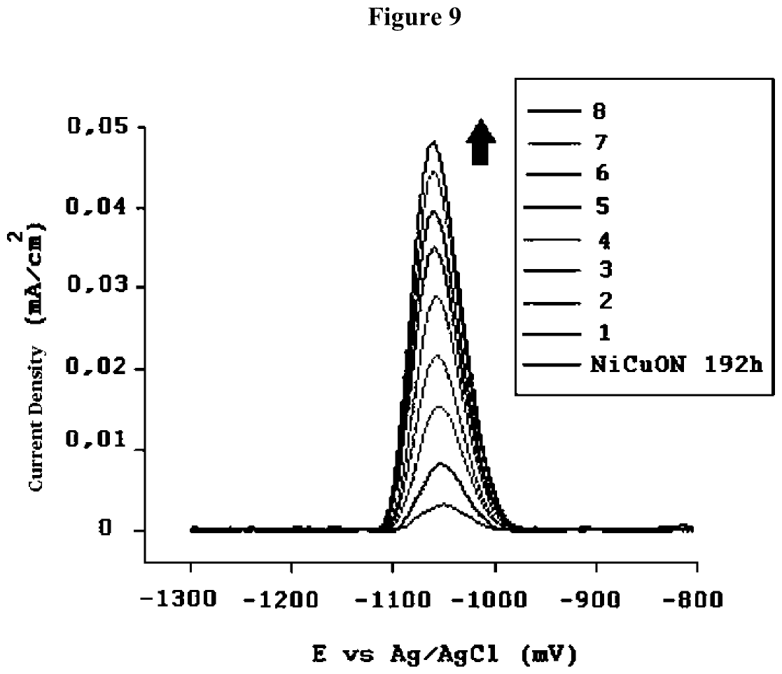

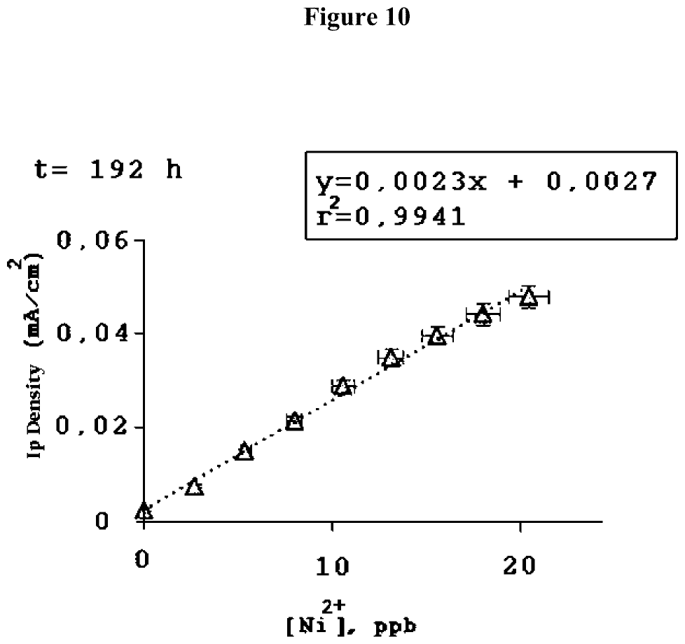

From this last analysis, it was found that on average 0.103 μg of nickel/cm²/week of the product NiCuOₓN_{y}-1043390250 are released. This value is much lower than the maximum limit allowed by the European Nickel Directive (0.5 μg/cm²/week) (Kovacevic, N., et al., 2012). It is also less than the maximum permissible limit in surgical grade steel AISI 316L (0.11 μg/cm²/week). By way of example, FIGS. 9 and 10 show the voltammogram obtained for this product and the respective calibration curve used to quantify the nickel released during the test.

This indicates that NiCuOₓN_{y} films can be considered as a good option to avoid the release of large quantities of Ni²⁺ ions from stainless steel, thus favoring biocompatibility and avoiding health problems related to sensitivity to this metal.

An important aspect worth noting is that, although NiCuOₓN_{y} films have nickel in their structure, this metal remains stable under simulated physiological conditions in the form of oxynitride. This shows that the properties of nickel should not be considered only in terms of the properties of the pure material in the bulk state, but that the properties of the nickel-matrix set should be taken into account due to synergistic effects.

### 6. Determination of the Optical Properties of Thin NiCuOₓN_{y} Films Deposited on Glass

Thin films of nickel-copper binary oxynitride NiCuOₓN_{y} were deposited on the surface of glass substrates of dimensions 2.0 cm long by 1.0 cm wide, by the method of sputtering RF in reactive phase under conditions similar to those mentioned above, where variations were also made in the flow of nitrogen, composition of Ni:Cu in the target, temperature and power applied to the target.

For the determination of the optical properties of the NiCuOₓN_{y} films, the transmittance and reflectance spectra of the films were taken in a UV-vis-NIR Varian Cary 5000 spectrophotometer in the range 300-2500 nm of wavelength at temperature ambient. Based on the spectra obtained, the following optical properties of the NiCuOₓN_{y} films were calculated: absorption coefficient, extinction coefficient, refractive index, static refractive index, optical gap energy, Urbach energy, thickness of the films, optical conductivity and optical density.

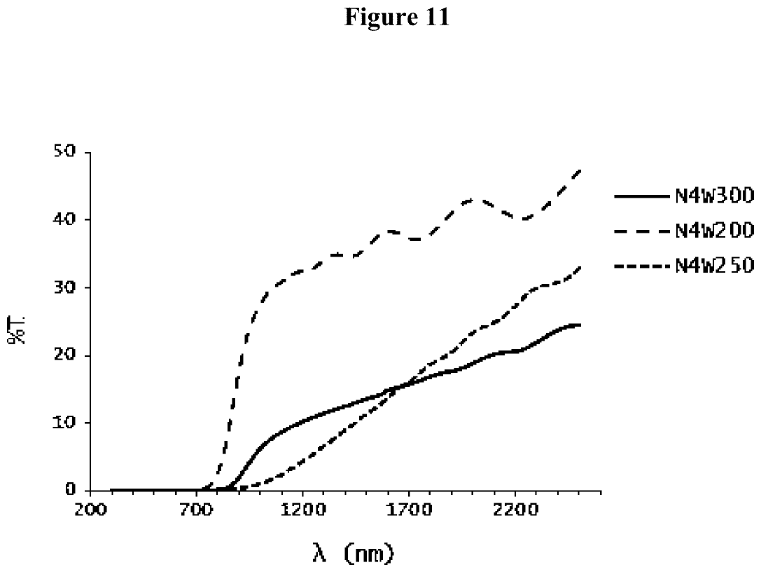

FIG. 11 depicts a comparison between the transmittance spectra of the NiCuOₓN_{y}-457314200, NiCuOₓN_{y}-457314250 and NiCuOₓN_{y}-457314300 products deposited in thin film form on glass substrates by the method of RF reactive sputtering, obtained when a power of 200, 250 and 300 W, is applied to the blank respectively.

### 6.1 Determination of the Absorption Coefficient (α)

The absorption coefficient (α) is one of the most important parameters in the study of the optical properties of a material and indicates the amount of photons that are absorbed by the material when a radiation of a certain wavelength strikes its surface (Huang, C, et al., 2002). From the recorded transmittance (T) and reflectance (R) values for each NiCuOₓN_{y} film, it is possible to determine the absorption coefficient (α) based on the expression reported by Shaban, M., et al. (2017).

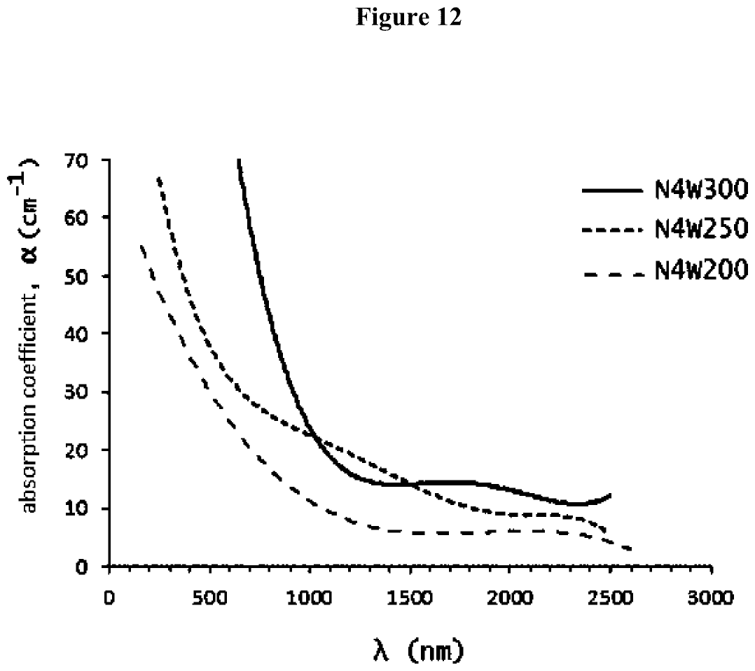

FIG. 12 depicts the variation of the absorption coefficient of the products NiCuOₓN_{y}-457314200 (N4W200), NiCuOₓN_{y}-457314250 (N4W250) and NiCuOₓN_{y}-457314300 (N4W300) as a function of the wavelength (λ). The products were deposited in thin film form on glass substrates by the sputtering method in RF reactive phase, applying a target power of 200, 250 and 300 W, respectively.

### 6.2 Determination of the Extinction Coefficient (k)

The value of the extinction coefficient (k), which reflects the absorption of electromagnetic waves in the material due to the inelastic scattering phenomenon, it can be determined from the absorption coefficient (α) by means of the equation reported in Hassanien, A., et al. (2016).

### 6.3 Determination of Optical Band Gap (Eg)

The optical band gap (Eg) can be determined from the Tauc expression reported in Shaban, M., et al. (2017). In the expression, variables such as Eₚₕₒₜₒₙ correspond to the discrete energy of the photon (where Eₚₕₒₜₒₙ=hu, where h is the Planck constant and u the frequency of the incident radiation). B is a constant independent of temperature but dependent on the refractive index ηo. Finally, n is the transition mode factor that depends on the nature of the material and defines the type of transition that takes place from the valence layer to the conduction layer (Hassanien, A., 2015). From the graph of (αhu)n as a function of hu, the value of the factor n can be identified by means of the slope of the curve with the highest linear dependence between (αhu)n versus hu and the value of Eg by linear extrapolation of the previous curve on the x axis when (αhu) n=0. For the NiCuOₓN_{y}, a transition mode factor value n=½ was determined, since with this value the highest degree of linearity is obtained. This indicates that the transition in NiCuOₓN_{y} is direct allowed.

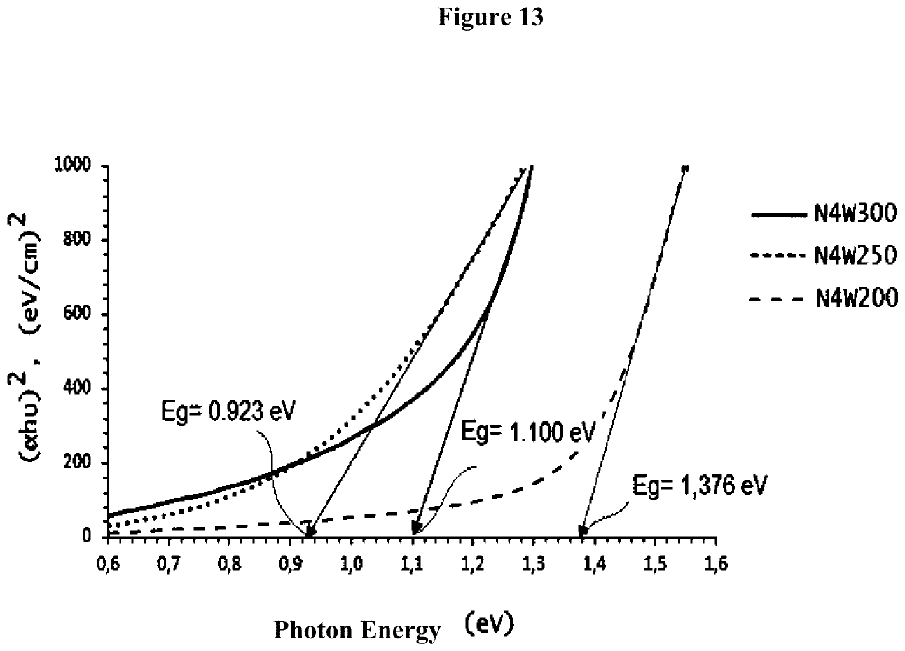

FIG. 13 depicts the variation of the factor (αhu)2 against the energy of the incident photon (hu). The highest degree of linearity was obtained for the optical transition mode factor n=½ indicating that a direct transition allowed in the NiCuOₓN_{y} material takes place. The determination of the optical band gap (Eg) is shown for the products NiCuOₓN_{y}-457314200 (N4W200), NiCuOₓN_{y}-457314250 (N4W250) and NiCuOₓN_{y}-457314300 (N4W300) deposited in thin film form on glass substrates by the method of cathode sputtering in RF reactive phase, obtained by applying a power to the target of 200, 250 and 300 W, respectively.

### 6.4 Determination of Urbach Energy (Eu)

The Urbach energy (Eu) refers to the width of the exponential absorption border (tail). The Eu values can be found from the slope of the curve in the graph of ln(α) vs hu. Eu is attributed to a disorder in the material that directs the tail in the valence and conduction bands (Shaban, M., et al., 2017).

### 6.5 Determination of the Refractive Index (η).

The refractive index (η) is an important parameter to be taken into account for applications in communication and optical devices (Li, T., et al., 2014). This parameter can be calculated from the method of Swanepoel, R., (1983) based on the interference fringes observed in the transmittance spectrum.

### 6.6 Determination of the Thickness of NiCuOₓN_{y} Films

The thickness of thin films of NiCuOxNy can be determined by the method of Swanepoel, R., (1983), taking the values of λ, and n for two consecutive ends by means of an iterative process.

### 6.7 Calculation of the Static Refractive Index

The static refractive index (ηo) can be determined from the Wemple-DiDomenico model based on the approximation of the simple harmonic oscillator, in which the dispersion of the refractive index (η) is described (Hassanien, A., et al., 2016). The model is based on the energy of the simple harmonic oscillator (Eo) and the scattering energy (Ed). By plotting the refractive index factor (n2−1)−1 as a function of the square of the energy of the photon (hu) 2, the parameters of the oscillator can be found. The graph is a straight line where the intercept with the y-axis corresponds to the value of (Eo/Ed) and the slope is equal to the reciprocal of the term (Ed/Eo).

Based on the values of Eo and Ed, the dielectric constant at zero frequency (ε) and the static refractive index (ηo) can be calculated when (hu) 2=0 in the Wemple-DiDomenico equation reported on Hassanien, A. & Akl, A. (2015).

### 6.8 Determination of the Optical Conductivity (σ)

The optical conductivity (σ) of thin semiconductor films depends on the energy of the optical band gap (Eg), absorption coefficient (α), refractive index (η), extinction coefficient (k) and the frequency of incident photons (Hassanien, A. & Akl, A., 2015).

### 6.9 Determination of the Optical Density (Dopt)

The optical density (Dₒₚₜ) or absorbance is proportional to the thickness of the film (d) and the absorption coefficient of the material (α) (Hassanien, A. & Akl, A., 2015). As an example, Table III shows the optical constants obtained for the product NiCuOₓN_{y}-457314200 (N4W200) deposited as a thin film on the surface of a glass substrate by the sputtering technique in RF reactive phase.

TABLE III
Optical constants determined by the method of Swanepoel, R., 1983, for the product
NiCuOₓN_{y}-4₅₇₃14₂₀₀ (N4W200). d average = 1620 μm, deviation δ = 0.075 μm.

| λ(nm) | T_{M} | Tₘ | n +/−0.004 | d (μm) +/−0.5 μm | α (cm⁻¹) | k × 10⁻⁵ | σ (s⁻¹) × 10¹⁴ | Dₒₚₜ |
|---|---|---|---|---|---|---|---|---|
| 2495 | 0.472 | 0.422 | 2.073 | 1620 | 4.744 | 9.42 | 2.493 | 0.157 |
| 2231 | 0.453 | 0.408 | 2.067 | 1620 | 5.782 | 10.3 | 2.779 | 0.191 |
| 1890 | 0.421 | 0.385 | 2.023 | 1620 | 5.812 | 8.74 | 3.211 | 0.192 |
| 1182 | 0.324 | 0.323 | 1.548 | 1620 | 7.374 | 6.93 | 3.929 | 0.244 |
| 1104 | 0.311 | 0.315 | 1.278 | 1620 | 7.674 | 6.74 | 3.473 | 0.254 |

Table IV shows a comparison between some of the optical constants obtained for the products NiCuOₓN_{y}-4₅₇₃14₂₀₀ (N4W200), NiCuOₓN_{y}-4₅₇₃4₂₅₀ (N4W250) and NiCuOₓN_{y}-4₅₇₃14₃₀₀ (N4W300) deposited in the form of a thin film on glass substrates by the spraying method cathode in RF reactive phase, obtained by applying a target power of 200, 250 and 300 W, respectively.

TABLE IV
Comparison between some of the optical properties determined for the
products NiCuOₓN_{y}-4₅₇₃14₂₀₀ (N4W200),
NiCuOₓN_{y}-4₅₇₃14₂₅₀ (N4W250) and
NiCuOₓN_{y}-4₅₇₃14₃₀₀ (N4W300).

| | Optical | Urbach | | Thickness |
|---|---|---|---|---|
| | band | Energy, | Static | of the |
| | energy, | Eu | refraction | film, |
| Material Code | Eg (eV) | (eV) | index, n₀ | d (μm) +/−12 μm |
| NiCuOₓN_{y}-4₅₇₃14₂₀₀ | 1.100 | 0.77 | 2.186 | 331 |
| NiCuOₓN_{y}-4₅₇₃14₂₅₀ | 0.923 | 1.89 | 1.993 | 481 |
| NiCuOₓN_{y}-4₅₇₃14₃₀₀ | 1.376 | 2.74 | 2.304 | 1620 |

In general, it was observed that depending on the deposition conditions, some films NiCuOₓN_{y} are highly absorptive in the region of the UV-vis spectrum (between 300 and 800 nm wavelength), while the NIR spectrum region presents low absorption and high transmittance values. This material could have application in optical devices such as infrared transmission windows (Tsilingiris, P., 2003) and as blocking filters of wavelengths between 200 and 750 nm also called high frequency pass filters (Rane, S. & Puri, V., 2002). On the other hand, some films of NiCuOₓN_{y} (as for example the product NiCuOₓN_{y}-10₃₂₃72₃₅₀) absorb in all the range of wavelengths of the UV-vis-NIR spectrum, therefore not they present transmittance.

In addition, it was observed that films NiCuOₓN_{y} have an optical band gap present between 0.9 and 0.4 eV and refractive index values between 1.8 and 2.4, and therefore have semiconducting characteristics making them potential materials in photovoltaic applications.

### DESCRIPTION OF SOME FORM OF CARRYING OUT THE INVENTION

In order to make the present invention more understandable, some specific examples that show how to carry out the invention are mentioned below:

### EXAMPLE 1

The product described here is called NiCuOₓN_{y}-18₄₃₃ 72₂ 5o. It is produced by the technique of sputtering RF in reactive phase on the surface of stainless steel AISI 316L, from a nickel-copper target whose composition is 72% Ni:28% Cu, base pressure 3.4×10^{˜3} Pa, working pressure 7.4×10^{˜1} Pa, argon flow 20.0 sccm, oxygen flow 2.00 sccm, nitrogen flow 18.0 sccm, temperature 433K, 250 W blank power, distance blank-substrate 5.0 cm and storage time 60 minutes. The product obtained presents black and/or gray coloration, and presents high biocompatibility.

### EXAMPLE 2

The product described here is called NiCuOₓN_{y}-10₅₇₃ 90₂ 5o—It is produced by the technique of sputtering RF in reactive phase on the surface of stainless steel AISI 316L, from a nickel-copper target whose composition is 90% Ni:10% Cu, base pressure 3.4×10^{˜3} Pa, working pressure 7.4×10^{˜1} Pa, argon flow 20.0 sccm, oxygen flow 2.00 sccm, nitrogen flow 10.0 sccm, temperature 573K, 250 W blank power, distance blank-substrate 5.0 cm and storage time 60 minutes. The product obtained shows brown coloration and presents moderate biocompatibility.

### EXAMPLE 3

The product described here is called NiCuOₓN_{y}-10₄₃₃ 72₂ 5o. It is produced by the technique of sputtering RF in reactive phase on the surface of stainless steel AISI 316L, from a nickel-copper target whose composition is 72% Ni:28% Cu, base pressure 3.4×10^{˜3} Pa, working pressure 7.4×10^{˜1} Pa, argon flow 20.0 sccm, oxygen flow 2.00 sccm, nitrogen flow 10.0 sccm, temperature 433K, target power 250 W, distance blank-substrate 5.0 cm and storage time 60 minutes. The product obtained shows blue and/or brown coloration and has excellent properties as a biocompatible material.

### EXAMPLE 4

The product described here is called NiCuOₓN_{y}-4₅ 7₃ 14₂ 5o. It is produced by the technique of sputtering RF in reactive phase on the surface of a glass substrate, from a nickel-copper target whose composition is 14% Ni:86% Cu, base pressure 3.4×10^{˜3} Pa, Working pressure 7.4×10^{˜1} Pa, argon flow 20.0 sccm, oxygen flow 2.00 sccm, nitrogen flow 4.0 sccm, temperature 573K, power of blank 250 W, distance blank-substrate 5.0 cm and storage time 60 minutes. The product obtained is a thin semiconductor optical film with band gap energy of 0.923 eV, Urbach energy 1.89 eV, static refractive index 1.99, highly absorbent in the UV-vis region and having high transmittance values in the NIR region of the electromagnetic spectrum.

### EXAMPLE 5

The product described here is called NiCuOₓN_{y}-457₃ 14₃ oo—It is produced by the RF sputtering technique in reactive phase on the surface of a glass substrate, from a nickel-copper target whose composition is 14% Ni:86% Cu, base pressure 3.4×10^{˜3} Pa, working pressure 7.4×10^{˜1} Pa, argon flow 20.0 sccm, oxygen flow 2.00 sccm, nitrogen flow 4.0 sccm, temperature 573K, blank power 300 W, distance blank-substrate 5.0 cm and storage time 60 minutes. The product obtained is a thin semiconductor optical film with band gap energy of 1.376 eV, Urbach energy 2.74 eV, static refractive index 3.304, highly absorbent in the UV-vis region and having high transmittance values in the NIR region of the electromagnetic spectrum.

### PATENT REFERENCES

U.S. Pat. No. 7,776,701 B2

US2010183766A1

U.S. Pat. No. 6,878,666 B2

U.S. Pat. No. 7,037,603 B2

US20120097227A1

U.S. Pat. No. 7,670,712 B2

US20080251121A1

U.S. Pat. No. 6,291,866 B1

US20090233424A1

### LITERATURE REFERENCES OTHER THAN PATENTS

Aguiar, R., Logvinovich, D., Weidenkaff, A., Rachel, A., Reller, A. & Ebbinhaus, S. (2008). The vast color spectrum of ternary metal oxynitride pigments. Dyes and pigments, 76 (1) 70-75.

Ahmed, M. & XinXin, G. (2016) A review of metal oxynitrides for photocatalyst. Inorganic Chemistry Frontiers, 3 (5) 578-590. Doi: 10.1039/C5QI0020217.

Ai, L, Fang, G., Yuan, L, Liu, N., Wang, M., Li, C, Zhang, Q., Li, J. & Zhao, X. (2008). Influence of substrate temperature on electrical and optical properties of p-type semitransparent conductive nickel oxide thin films deposited by radio frequency sputtering, Applied Surface Science, 254 (1) 2401-05.

Aiken, Z., Hyett, G., Dunnill, C, Wilson, M., Pratten, J. and Parkin, I. P. (2010) Antimicrobial Activity in Thin Films of Pseudobrookite-Structured Titanium Oxynitride under UV Irradiation Observed for Escherichia coli. Chemical Vapor Deposition, 16: 19-22. Doi: 10.1002/cvde.200904285.

Al-Kuhaili, M. (2008). Characterization of copper oxide thin films deposited by the thermal evaporation of cuprous oxide (Cu₂O), Vacuum, 82 (1) 623-29.

Aroutiounian, V., Martirosyan, K. & Soukiassian, P. (2006) Almost zero reflectance of a silicon oxynitride/porous silicon double layer antireflection coating for silicon photovoltaic cells. Journal of Physics D: Applied Physics, 39 (8) 1623.

Balaceanu, M., Braic, V., Braic, M. & Kiss, A. (2008). Structural, mechanical and corrosion properties of TiOxNy/ZrOxNy multilayer coatings. Surface & Coatings Technology, 202 (1), 2384-88.

Balogun, M., Zeng, Y., Qiu, W., Onasanya, A., Olaniyi, T. & Tong, Y. (2015). Three-dimensional nickel nitride (Ni₃N) nanosheets: Free standing and flexible electrode for lithium ion batteries and supercapacitors, Journal of Materials Chemistry A, 137 (12) 41 19-25. Doi: 10.1021/ja51 19495. [0152] Bhattacharyya, S., Gayen, R., Paul, R. & Pal, K. (2009). Determination of optical constants of thin films from transmittance trace, Thin Solid Films, 517 (1) 5530-36.

Bianchi, M., Gambardella, A., Berni, M., Panseri, S., Montesi, M., Lopomo N., Tampieri, A., Marcacci, M. & Russo, A. (2016). Surface morphology, tribological properties and in vitro biocompatibility of nanostructured zirconia thin films. Journal of Materials Science: Materials in Medicine, 27 (5) 96. Doi: 10.1007/S10856-016-5707-4.

Boukrouh, S., Kerdoud, D., Medjani, F., Segni, R. & Kezai, T. (2012). Reactive sputtering DC magnetron-deposited Ti02 thin films intended for photoelectrolysis of water for hydrogen production, International Conference on Renewable Energies for Developing Countries (REDEC), Beirut. Pp. 1-4. Doi: 10.1 109/REDEC.2012.6416705.

Buecker, P., Gebhardt, M. & Weber, K. (2016). Osteosarcoma: a detailed review. Retrieved from: http://sarcomahelp.org/osteosarcoma.html?tpm=1_2

Caglar, M., Caglar, Y. & llican, S. (2006). The determination of the thickness and optical constants of the ZnO crystalline thin film by using envelope method, Journal of Optoelectronics and Advanced Materials, 8 (4) 1410-13.

Carvalho, P., Borges, J., Rodriguez, M., Barradas, N., Alves, E., Espinos, J., González-Elipe, J., Cunha, L, Marques, L, Vasilevskiy, M. & Vaz, F. (2015). Optical properties of zirconium oxynitride films: The effect of composition, electronic and crystalline structures. Applied Surface Science, 358 (1) 660-9.

Caskey, C, Richards, R., Ginley, D. & Zakutayev, A. (2014). Thin film synthesis and properties of copper nitride: a metastable semiconductor, Materials Horizons, 1 (1) 424-30. DOI: 10.1039/c4mh00049h.

Chang, Y., Huang, H., Lai, C, Hsu, J., Shieh, T., Wu, A. & Chen, C. (2013) Analyzes of Antibacterial Activity and Cell Compatibility of Titanium Coated with to Zr—CN Film. PloS One, 8 (2) e56771. Doi: 10.1371/iournal.pone.0056771.

Clavijo, D., Alfonso, J., Cardozo, C, Casadiego, C. & Perea, A. (2010) Towards a new generation of biomaterials. First part, 24 (3) 168-77.

Cubillos, G., Bethencourt, M. & Olaya, J. (2015) Corrosion resistance of zirconium oxynitride coatings deposited via DC unbalanced magnetron sputtering and spray pyrolysis-nitriding. Applied Surface Science, 327 (1) 288-295. Doi: 10.1016/.apsusc.2014.1 1.168.

Cubillos, G., Olaya, J., Clavijo, D., Alfonso, J., Bethencourt, M. (2013) Corrosion resistance and biocompatibility of zirconium oxynitride thin film growth by RF sputtering, Revista Mexicana de Fisica, 58 (4) 328-34

Du, Y., Huang, R., Song, R., Ma, L, Liu, C, Li, C. & Cao, Z. (2007). Effect of oxygen inclusion on microstructure and thermal stability of copper nitride thin films, Journal of Materials Research Society, 22 (11) 3052-57.

Dunn, A., Buffa, E., Hanshaw, D. & Farrell, M. (2012) Osteosarcoma at the site of titanium orthopaedic implants in a dog, Australian Veterinary Journal, 90 (2) 39-43.

Ellenrieder, M., Haenle, M., Lenz, R., Bader, R., & Mittelmeier, W. (2011). Titanium-copper-nitride coated spacers for two-stage revision of infected total hip endoprostheses. GMS Krankenhaushygiene Interdisziplinár, 6 (1), Doc16. Doi: http://doi.Org/10.3205/dgkh000173.

Escobar, A. (2012). Economic prostheses thanks to hydroxyapatite. A Newspaper, (Ed. 154). National university of Colombia.

Evrard, L., Waroquier, D. & Parent, D. (2010). Allergies to dental metais. Titanium: A new allergen, Revue medicale de Bruxelles, 31 (1) 44-9.

Ferreira, M., Pereira, M., Garcia, F., Sousa, J. & de Carvalho, G. (2003). Comparative study of metallic biomaterials toxicity: a histochemical and immunohistochemical demonstration in mouse spleen. Journal of Trace Element in Medical Biology, 17 (1) 45-49.

Fuertes, A. (2015). Metal oxynitride as emerging materials with photocatalytic and electronic properties. Materials Horizons, 2 (1) 453-61. [0170] Gomaa, M., Boshta, M., Farag, B. & Osman, M. (2016). Structural and optical properties of nickel oxide thin films prepared by chemical bath deposition and spray pyrolysis techniques, Journal of Materials Science: Materials in Electronics, 27 (1) 71 1-17.

Hassanien, A. & Akl, A. (2015). Influence of composition on optical and dispersion parameters of thermally evaporated non-crystalline Cd50S50-xSex thin films, Journal of Alloys and Compounds, 648 (1) 280-90.

Hassanien, A., Aly, K. & Akl, A. (2016). Study of optical properties of thermally evaporated ZnSe thin films annealed at different pulsed laser powers, Journal of Alloys and Compounds, 685 (1) 733-42.

Hossaina, A., Al-Gaashani, R., Hamoudi, H., Al-Marri, M., Hussein, I., Belaidi, A., Merzougui, B., Alharbia, F. & Tabet, N. (2017). Controlled growth of Cu20 thin films by electrodeposition approach, Materials Science in Semiconductor Processing, 63 (1) 203-1 1.

Huang, C, Zhang, G., Chen, Z., Huang, X. & Shen, H. (2002). Calculation of the absorption coefficients of optical materials by measuring the transmissitives and refractive indexes, Optics and Laser Technology, 34 (1) 209-1 1.

ISO 10993-5: 2009 Biological Evaluation of Medical Devices. Part 5: Tests for In Vitro Cytotoxicity. International Organization for Standardization; Geneva, Switzerland: 2009.

Jokanovic, V., Jokanovic, B., Izvonar, D. & Dacic, B. (2008). Thin films of SiO2 and hydroxyapatite on titanium deposited by spray pyrolysis. J Mater Sci Mater Med, 19 (5) 1871-9.

Jouan, P., Tricoteaux, A. & Nicolás, N. (2006). Elaboration of nitride thin films by reactive sputtering. Rem: Magazine Escola de Minas, 59 (2), 225-232. Doi: https://dx.doi.org/10.1590/S0370-44672006000200013.

Kim, Y. & Wadley, H. (2008) Lithium phosphorous oxynitride films synthesized by a plasma-assisted directed vapor deposition approach. Journal of Vacuum Science & Technology A, 26 (1) 174-183. [0179] Kumar, S., Murugesan, S., Suresh, S. & Raj, S. (2013). Nanostructured CuO thin films prepared through sputtering for selective solar absorbers, Journal of Solar Energy, vol 2013, article ID 147270. Doi: 10.1 155/2013/147270.

Lee, E., Kim, T., Bendyad, A., Hur, J., Park, G. & Jeon, S. (2016) High mobility and high stability glassy metal oxynitride materials and devices. Scientific Reports, 6 (1) 23940. Doi: 10.1038/srep23940

Li, T., Chung, C, Han, C, Hsieh, P., Chen, K. & Lin, J. (2014). Effects of prestrain applied to poly (ethylene terephthalate) substrate before coating of indium-tin-oxide film on film quality and optical, electrical and mechanical properties. Ceramics International, 40 (1-A) 591-603.

Liu, H., Zheng, W., Yan, X. & Feng, B. (2008). Studies on electrochromic properties of nickel oxide thin films prepared by reactive sputtering, Journal of Alloys and Compounds, 462 (1) 356-61.

Lu, Y., Le Paven-Thivet, C, Benzerga, R., Le Gendre, L., Sharaiha, A., Tessier, F. & Cheviré, F. (2013) Influence of the sputtering reactive gas on the oxide and oxynitride La—Ti—ON deposition by RF magnetron sputtering, Applied Surface Science, 264 (1) 533-537. Doi: 10.1016/]. 3ρ5υ5θ.2012.10.059,

Lu, Y., Huang, W., Yang, J. & Chuang, H. (2002). Properties of nickel oxide thin films deposited by RF reactive magnetron sputtering, Thin Solid Films, 420-42 (1) 54-61.

Lumey, M. & Dronskowski, R. (2006) Quantum chemical calculations of transition metal oxynitrides=Quantenchemische Rechnungen an Übergangsmetalloxidnitriden. (Doctoral Thesis), RWTH Aachen University, pp 1-104.

Majeed, A., He, J., Jiao, L, Zhong, X., & Sheng, Z. (2015). Surface properties and biocompatibility of nanostructured Ti0₂ film deposited by RF magnetron sputtering. Nanoscale Research Letters, 10 (1) 56. http://doi.Org/10.1186/S11671-015-0732-7

Marinescu, C, Sofronia, A., Anghel, E., Baies, R., Constantin, D., Seciu, A., Gingu, O. & Tanasescu, S. (2017). Microstructure, stability and biocompatibility of hydroxyapatite-titania nanocomposites formed by two step sintering process. Arabian Journal of Chemistry, http://dx.doi Org/10.1016/j.arabjc.2017.01.019.

Maruyama, T. & Morishita, T. (1995). Copper nitride thin films prepared by radio-frequency reactive sputtering, Journal of Applied Physics, 78 (6) 4104. Doi: http://dx.doi.Org/10.1063/1.359868,

Mitran, V., Vasilescu, C, Drob, S., Osiceanu, P., Calderon-Moreno, J. M., Tabirca, M.-C, Cimpean, A. (2015). Biological Behavior and Enhanced Anticorrosive Performance of the Nitrided Superelastic Ti—23Nb—0.7Ta—2Zr—0.5N Alloy. BioMed Research International, 2015, 261802. Doi: http://doi.Org/10.1155/2015/261802,

Musil, J., Baroch, P., Vlcék, J., Nam, K. & Han, J. (2005). Reactive magnetron sputtering of thin films: present status and trends. Thin Solid Films, 475 (1) 208-218. Do: 10.1016/.tsf.2004.07.041.

Navarro, M., Michiardi, A., Castaño, O. & Planell, J. (2008) Biomaterials in orthopaedics: Review, Journal of the Royal Society Interface, 5 (1) 1 137-58. Doi: 10.1098/rsif.2008.0151

Nayan, N., Sandan, M., Wei, L, Ahmad, M., Lias, J., Md. Shakaff, A., Zakaria, A. & Mohd, A. (2016). Sputter deposition of cuprous and cupric oxide thin films monitored by optical emission spectroscopy for gas sensing applications, Proceed Chemistry, 20 (1) 124-29.

Ng, J., Chang, M., Yang, J., Lin, T., Lo, S., Yeh, C, Lin, H., Kao, J., Tu, Y., Lin, H., Peng, C, Jeng, P., Young, B. & Chuang, H. Self-aligned insulated film for high-k metal gate device, US 20130056837A1. (US Cl. 257,410, Int. Cl. H01 L 29/772, 21/336, 21/28), Mar. 7, 2013, application Ser. No. 13/244,365, Sep. 24, 2011.

Norambuena, G., Patel, R., Karau, M., Wyles, C, Jannetto, P., Bennet, K., Hassen, A. & Sierra, R. (2016). Antibacterial and biocompatible titanium-copper oxide coating may be a potential strategy to reduce periprosthetic infection: an in vitro study, Clinical Orthopedics and Related Research, 475 (3) 1-1 1.

Parsapour, A., Khorasani, S. & Fathi, M. (2013). Corrosion behavior and biocompatibility of hydroxyapatite coating on H₂S0₄ passivated 316L SS for human body implant. Acta Metallurgica Sinica, 26 (4) 409-415. Doi: 10.1007/S40195-012-0212-3.

Peng, D., Bai, X., Chen, B. (2006). Effect of copper ions implantation on corrosion behavior of zircaloy-2 in 1 MH₂S0₄, Materials Chemistry and Physics, 98 (1) 337-43.

Pichugina, V., Pustovalovaa, A., Konishcheva, M., Khlusova, I., Ivanovaa, N., Zhileia, S. & Gutorb, S. (2016). In-vitro Dissolution and Structural and Electrokinetic Characteristics of Titanium-Oxynitride Coatings Formed via Reactive Magnetron Sputtering, Journal of Surface Investigation. X-ray, Synchrotron and Neutron Techniques, 10 (2) 282-91.

Platzman, I., Brener, R., Haick, H. & Tannenbaum, R. (2008). Oxidation of Polycrystalline Copper Thin Films at Ambient Conditions, Journal of Physics and Chemistry C, 12 (1) 1 101-08.

Pohrelyuk, I., Fedirko, V., Tkachuk, 0. & Proskurnyak, R. (2014) Corrosion Resistance of Titanium Alloys with Oxynitride Coatings in Concentrated Inorganic Acids. Materials Science, 50 (2) 269-276. Doi: 10.1007/s1 1003-014-9717-4.

Probst, J., Gbureck, U. & Thull, R. (2001). Binary nitride and oxynitride PVD coatings on titanium for biomedical applications. Surface and Coatings Technology, 148 (1) 226-33. Doi: 10.1016/S0257-8972 (01) 01357-3.

Ramalingan, M., Haidar, Z., Ramakrishna, S., Kobayashi, H. & Haikel, Y. (2012) Integrated biomaterials in tissue engineering (1st Ed): Scrivener Publishing, pp 120-130.

Rane, S. & Puri, V. (2002). Thin film, thick film microstrip band pass filter: a comparison and effect to bulk overlay, Microelectronics Reliability, 42 (12) 1953-58.

Ratner, B. (2004) Biomaterials science: An introduction to materials in medicine, (2nd Ed). Elsevier Academic Press, pp. 67-173.

Rim, Y., Ok, K., Yang, Y., Chen, H., Bae, S., Wang. C., Huang, Y., Park, J. & Yang, Y. (2016) Boosting responsivity of organic-metal oxynitride hybrid heterointeriace phototransistor, ACS Applied materials and interiaces, 15 (8) 14665-70. Doi: 10.1021/acsami.6b02814

Sachtler, W., Dorgelo, G. (1965) The surface of copper-nickel alloy films I work function and phase composition, Journal of catalysis, 4 (6) 654-64.

Sánchez, J., Bolarin, M., Tones, G., Cortes, C. & Betancourt, J. (2010) Mechanical alloying of biocompatible Co—28Cr—6Mo alloy. Journal of materials Science. Materials in medicine, 21 (7) 2021-2026. Doi: 10.1007/s10856-010-4066-9.

Santana, G., Melo, O., Aguilar-Hernandez, J., Mendoza-Perez, R., Monroy, M., Escamilla-Esquivel, A., Lopez-Lopez, M., Moure, F., Hernandéz, L. & Contreras-Puente, G. (2013) Photoluminescence Study of Gallium Nitride Thin Films Obtained by Infrared Cióse Space Vapor Transport. Materials, 6 (1) 1050-1060. Doi: 10.3390/ma6031050

Santonen, T., Stockmann, H. & Zitting, A. (2010). Review of toxicity of stainless steel. Institute of occupational health, Helsinki: Finland. ISBN 978-952-261-039-3.

Saravia, M. (2012) Sputter deposition of MgO thin films: The effect of cation substitution (PhD thesis), University Gent.

Shaban, M., Zayed, M. & llican, S. (2017). Nanostructured ZnO thin films for self-cleaning applications, RSC Advances, 7 (1) 617-31. [021 1] Swanepoel, R. (1983). Determination of the thickness and optical constants of amorphous silicon, Journal of Physics E: Science Instruments, 16 (1) 1214-22.

Sowiñska, M., Brizzi, S., Das, C, Kárkkánen, I., Naumann, F., Gargouri, H., Henkel, K. & SchmeiBer, D. (2016) Analysis of nitrogen species in titanium oxynitride ALD films, Applied Surface Science, 381 (1) 42-47. Doi: 10.1016/j.apsusc.2016.02.096

Takata, T., Pan, C. & Domen, K. (2015) Recent progress in oxynitride photocatalyst for visible-light-driven water splitting. Science and Technology of Advanced materials, 16 (1) 033506.

Torrell, M., Cunhaa, L, Cavaleiro, A., Alvesc, E., Barradasc, N. & Vaza, F. (2010). Functional and optical properties of Au: Ti0₂ nanocomposite films: The influence of thermal annealing, Applied Surface Science, 256 (1) 6536-42.

Tsilingiris, P. (2003). Comparative evaluation of the infrared transmission of polymer films, Energy Conversion and Management, 44 (1) 2839-56.

Tuwei, A., Ketui, D. & Njogu, S. (2016). Effects of Annealing and Oxygen/Nitrogen Ratio on Transmittance of Copper Oxynitride Thin Films, International Journal of Thin Films Science and Technology, 5 (1) 51-54. Doi: http://dx.doi.Org/10.18576/ijtfst/050108.

Vaz, F., Martin, N., Fenker, M. (2013) Metallic oxynitride thin films by reactive sputtering and related deposition methods: process, properties and applications, Bentham Science Publishers, pp. 64-167.

Vempaire, D., Miraglia, S., Sulpice, A., Ortega, L, Hlil, E., Fruchard, D. & Pelletier, J. (2004). Structure and magnetic properties of nickel nitride thin film synthesized by plasma-based ion implantation, Journal of Magnetism and Magnetic Materials, 272-276 (1) e843-e844.

Wierzchoñ, T., Ulbin-Pokorska, I. & Sikorski, K. (2000) Corrosion resistance of chromium nitride and oxynitride layers produced under glow discharge conditions. Surface and coatings Technology, 30 (2-3) 274-79. Doi: 10.1016/S0257-8972 (00) 00696-4

Xi, Y., Huang, B., Djurisic, A., Chan, C, Leung, F., Chan, W. & Au, T. (2009). Electrodeposition for antibacterial nickel-oxide-based coatings, Thin Solid Films, 517 (24) 6527-30. Doi: https://doi.Org/10.1016/j.tsf.2009.04.018.

Yang, X., Li, C, Yang, B., Wang, W. & Qian, Y. (2004). Optical properties of titanium oxynitride nanocrystals synthesized via a thermal liquid-solid metathesis reaction, Chemical Physics Letters, 383 (5-6) 502-6.

Yue, G., Yan, P. Liu, J., Wang, M., Li, M. & Yuan, X. (2005). Copper nitride thin film prepared by reactive radiofrequency magnetron sputtering, Journal of Applied Physics, 98 (103506) 1-7. Doi: http://dx.doi.Org/10.1063/1.2132507.

Zakutayev, A. (2016) Design of nitride semiconductors for solar energy conversion. Journal of Materials Chemistry A, 4 (18) 6742-6754. Doi: 10.1039/C5TA09446A

Zakutayev, A., Baranowski, L, Welch, A., Wolden, C. & Toberer, E. (2014). Comparison of Cu₂SnS₃ and CuSbS₂ as potential solar cell absorber, Photovoltaic Specialist Conference (PVSC), IEEE 40th, pp. 2436-2438.

Zhang, Y. (2015). Thermal oxidation fabrication of NiO film for optoelectronic devices, Applied Surface Science, 344 (1) 33-7. \

All patents, patent applications and publications cited in this application including all cited references in those patents, applications and publications, are hereby incorporated by reference in their entirety for all purposes to the same extent as if each individual patent, patent application or publication were so individually denoted.

While the many embodiments of the invention have been disclosed above and include presently preferred embodiments, many other embodiments and variations are possible within the scope of the present disclosure and in the appended claims that follow. Accordingly, the details of the preferred embodiments and examples provided are not to be construed as limiting. It is to be understood that the terms used herein are merely descriptive rather than limiting and that various changes, numerous equivalents may be made without departing from the spirit or scope of the claimed invention.

1-11. (canceled)

12. A thin film of a nickel-copper binary oxynitride wherein said nickel-copper binary oxynitride has the chemical formula NiCuOxNy wherein the value of x is between 0.25 and 1.0; and the value of y is between 0.5 and 0.8.

13. The thin film of nickel-copper binary oxynitride (NiCuOxNy) according to claim 12, wherein said film has a thickness between 700 and 2100 nm and wherein said thin film is deposited on a solid substrate of stainless steel AISI 316L and/or glass (1).

14. A process for the manufacture of the nickel-copper binary oxynitride thin film (NiCuOₓN_{y}) of claim 12, comprising the following steps:
(a) polishing the surface of a stainless steel AISI 316L substrate up to a granulometry between 500 and 700 grit;
(b) cleaning the substrate with distilled water and isopropanol;
(c) inserting the cleaned substrate of step (b) in a sample holder (18) of the vacuum chamber of a PVD-Magnetron Sputtering RF reactor;
(d) injecting into the vacuum chamber argon (6) gas and oxygen (7) and nitrogen (8) as reactive gases;
(e) turning on the radiofrequency source and the magnetron located inside the vacuum chamber on which the cathode or target (3) is located, containing the copper and nickel elements to be deposited;
(f) depositing a thin film of the nickel-copper binary oxynitride coating by RF reactive sputtering at a base pressure between 3.0×10⁻³ and 3.5×10⁻³ Pa; and
(g) depositing a film of nickel-copper binary oxynitride coating by RF reactive sputtering at a working pressure between 7.2×10⁻¹ and 7.6×10⁻¹ Pa.

15. The process for the manufacture of the nickel-copper binary oxynitride thin film (NiCuOₓN_{y}) according to claim 14, wherein the inert gas is argon (6) and the flow of this gas in the chamber of Vacuum is between 18.0 and 22.0 sccm.

16. The process for the manufacture of the nickel-copper binary oxynitride thin film (NiCuOₓN_{y}) according to claim 14, wherein the reactive gases are oxygen (7) and nitrogen (8), where the flow of oxygen remains constant at 2.00 sccm and nitrogen between 4.00 and 18.0 sccm.

17. The process for manufacturing the nickel-copper binary oxynitride thin film (NiCuOₓN_{y}) according to claim 14, wherein the target or cathode (3) is nickel (99.9% in purity) and copper (99.9% in purity) with nickel composition between 14% and 90% by weight.

18. The process for manufacturing the nickel-copper binary oxynitride thin film (NiCuOₓN_{y}) according to claim 14, wherein the temperature of the substrate (1) during deposition is between 323 K and 573 K.

19. The process for manufacturing the nickel-copper binary oxynitride thin film (NiCuOₓN_{y}) according to claim 14, wherein the target power is between 200 and 350 W, constant blank-substrate distance of 5.0 cm and the constant deposit time of 60 minutes.

20. The process for the fabrication of the nickel-copper binary oxynitride thin film (NiCuOₓN_{y}) according to claim 14, wherein at the operating conditions: nitrogen flow between 10.0 and 18.0 sccm, blank composition 72% Ni—28% Cu, temperature 433 K and power 250 W, the coating is biocompatible according to ISO Classification 10993-12.

21. The process for the manufacture of the nickel-copper binary oxynitride thin film (NiCuOₓN_{y}) according to claim 14, wherein at the operating conditions: nitrogen flow 10.0 sccm, blank composition 90% Ni—10% Cu, temperature 433 K and power 250 W, the film generates a coating of hydroxyapatite greater than 39% of the surface of the material, which favors osseointegration, and has a nickel release rate under simulated physiological conditions (0.103 g of nickel/cm²/week).

22. The process for the manufacture of the nickel-copper binary oxynitride thin film (NiCuOₓN_{y}) according to claim 14, wherein at the operating conditions: nitrogen flow between 4.00 and 18.0 sccm, composition of the target bimetallic Ni:Cu between 14% and 90% in nickel, temperature between 323 K and 573 K, and power between 200 and 350 W, the film obtained has a band gap energy between 0.8 and 2.5 eV; has Urbach energy between 0.7 and 2.8 eV; has static refractive index between 1.8 and 2.98; is absorbent in the UV-vis range with wavelengths between 200 and 800 nm; have transmittance in the infrared region of the electromagnetic spectrum between 800 and 2500 nm.
